(19) United States
(12) Patent Application Publication
(10) Pub. No.: US 2024/0054399 A1
(43) Pub. Date: Feb. 15, 2024

(54) NANOSECOND EXECUTION OF MACHINE LEARNING ALGORITHMS AND NANOSECOND ANOMALY DETECTION AND ENCODED DATA TRANSMISSION USING AUTOENCODERS WITH DECISION TREE GRID IN FIELD PROGRAMMABLE GATE ARRAY AND OTHER ELECTRONIC DEVICES

(71) Applicant: UNIVERSITY OF PITTSBURGH-OF THE COMMONWEALTH SYSTEM OF HIGHER EDUCATION, PITTSBURGH, PA (US)

(72) Inventors: TAE MIN HONG, PITTSBURGH, PA (US); BENJAMIN T. CARLSON, SANTA BARBARA, CA (US); JOERG H. STELZER, CHEMNITZ (DE); STEPHEN T. ROCHE, NAPERVILLE, IL (US); STEPHEN T. RACZ, NORTH HUNTINGDON, PA (US); DANIEL C. STUMPP, NEW CUMBERLAND, PA (US); QUINCY BAYER, MURRYSVILLE, PA (US); BRANDON R. EUBANKS, PITTSBURGH, PA (US)

(73) Assignee: UNIVERSITY OF PITTSBURGH-OF THE COMMONWEALTH SYSTEM OF HIGHER EDUCATION, PITTSBURGH, PA (US)

(21) Appl. No.: 18/264,877

(22) PCT Filed: Mar. 3, 2022
(86) PCT No.: PCT/US2022/018703

§ 371 Date: Aug. 9, 2023

Related U.S. Application Data
(60) Provisional application No. 63/157,160, filed on Mar. 5, 2021.
(60) Provisional application No. 63/195,334, filed on Jun. 1, 2021.

(51) Int. Cl. G06N 20/00

(52) U.S. Cl. CPC G06N 20/00

(57) ABSTRACT

A system for providing a boosted decision tree (BDT) for use on an electronic device to provide an event score based on a user input event, where the device includes: a machine learning trainer configured to create a trained BDT from an untrained BDT by determining parameters for the untrained BDT; a nanosecond optimizer configured to create an optimized BDT, the nanosecond optimizer including at least one of a tree flattener, a tree merger, a score normalizer, a tree remover, and a cut eraser; and a converter coupled to the nanosecond optimizer and configured to receive the optimized BDT from the nanosecond optimizer and convert the optimized BDT to a language for high-level-synthesis to produce a hardware description language representation of the optimized BDT, wherein the hardware description language representation of the optimized BDT is structured and configured to be implemented in firmware provided on the electronic device.

### CROSS-REFERENCE TO RELATED APPLICATIONS

This patent application claims the priority benefit under 35 U.S.C. § 119(e) of U.S. Provisional Application No. 63/157,160, filed on Mar. 5, 2021 and U.S. Provisional Application No. 63/195,334 filed on Jun. 1, 2021, the contents of which are herein incorporated by reference.

### GOVERNMENT CONTRACT

This invention was made with government support under grant No. DE-SC0007914 by the Department of Energy, grant Nos. 1624739 and 1948993 by the National Science Foundation and Subcontract 0000359437 via Brookhaven Science Associates by the Department of Energy. The government has certain rights in the invention.

### BACKGROUND OF THE INVENTION

### 1. Field of the Invention

The present invention relates to a system, apparatus and method for nanosecond execution of machine learning (ML) algorithms and nanosecond anomaly detection and encoded data transmission in an electronic device, particularly, to a system, apparatus, and method for nanosecond event classification using boosted decision trees (BDT) in a Field Programmable Gate Arrays (FPGA) and a system, apparatus, and method for nanosecond anomaly detection and encoded data transmission using autoencoders with decision tree grid in an FPGA.

### 2. Description of the Related Art

Machine learning (ML), which is also referred to as artificial intelligence (AI) or multivariate analysis (MVA), can be used to distinguish two or more types of events, such as to discern the images of persons from trees or to differentiate the patterns of energy deposits of electrons from photons in physics experiments. ML methods can also be used in regression problems to estimate, e.g., the energy of the electron from the pattern of energy deposits. The use of such a machine learning method for uncategorized events is done in two steps. First, the training step determines the structure and parameters that optimally separate the event categories based on the characteristic variables. Second, the training step is complete, the machine learning method together with the structure and parameters can evaluate the uncategorized events. The evaluation step either places the uncategorized events into one of the categories or gives the probability of the events of being in one of the categories.

A boosted decision trees (BDT) is a machine learning method based on a collection of decision trees. A single decision tree evaluates an event, e.g., an image of a person or car, using a tree-like model of a nested decision-making process and its possible outcomes. The two steps to analyze an event—the training step and the evaluation step—use a set of variables that characterize the event by a set of numerical values. In a two-category problem, as in the above example of person from trees, an event may be classified as signal (S) for the former or background (B) for the latter, based on the set of numerical values for the event. In a more general n-category problem—e.g., images of persons, car, and bikes for the n=3 case—a decision tree can categorize an event as category 1 (S1), category 2 (S2), up to the n-th category (Sn). The structure of a decision tree is a sequence of binary splits. The training step determines the threshold values of each node and the probability values of each terminating nodes. In order to train the decision tree, a set of events, where the category of each event is known a priori, is normally used. The terminating nodes of a decision tree may give a result that is indeterminate, e.g., in the extreme case, a 50% probability for S and a 50% probability for B in a two-category problem. The training step then considers a revised data sample containing a larger fraction of the misclassified events, made larger by a boost factor greater than unity for each such event, to re-evaluate the threshold values of each node and the probability values of each terminating nodes. This is repeated hundreds or thousands of times until the improvement from subsequent repetition becomes negligible. The ensemble of the set of boost factors for each iteration, along with the set of all of the corresponding thresholds and terminating nodes for each decision tree, is the trained BDT. The training step is typically done once with the training data sample after which the trained BDT is used to evaluate a data sample containing undetermined events.

Evaluating a BDT, as well as other machine learning algorithms, on Field Programmable Gate Arrays (FPGA) is a developing field. For example, a number of physics experiments, which utilize multi-level FPGA- and Application Specific integrated Circuits (ASIC)-based trigger systems that issue decisions to save a fraction of real-time data with a latency of a few microseconds, have adapted machine learning algorithms to be evaluated on an FPGA. Existing implementations of machine learning algorithms on an FPGA—or any other electronic devices, e.g., electronic switches or ASICs—face challenges in latency and resource usage due to the complexity of the algorithms. Additionally, despite the fact that there are a wide range of applications for BDTs on FPGAs, both academic and commercial, much of the work largely remains focused on specific individual applications, rather than a coherent set of tools and novel algorithms to evaluate BDT on FPGA.

Further, an unsupervised ML method such as an autoencoder may be trained to recognize ordinary data and detect anomalous phenomena with respect to the ordinary data. Recent studies regarding the unsupervised detection of new physics focuses on the analysis of existing data recorded by, e.g., Large Hadron Collider (LHC) experiment, and tend to assume that the data is already available, (e.g., saved by the existing multi-level trigger system of an apparatus that records the energy deposits and their patterns coming from the collisions). However, the data may not be already available for, e.g., cases in which the decay products are relatively “soft” The LHC offers an environment with an abundance of ordinary data at a high 40 MHz rate, where anomalous phenomena may occur at a very low rate, e.g., 10 μHz. In order to effectively account for such potential rare phenomena, there needs to be a trigger capable of ignoring the large amount of ordinary data while detecting and alerting the rare anomalous events at high efficiency (e.g., achieving latency of tens of nanoseconds). Moreover, compressing sensor data using autoencoder for transmitting the compressed encoded data over a large distance to be decoded later is important in characterizing the high rate or incoming data at the nanosecond timescale.

There is a room for improvement in evaluating BDT, as well as other machine learning algorithms more generally, in electronic devices such as an FPGA and ASIC.

There is a need for accurately and efficiently detecting anomaly associated with ordinary data using autoencoder in electronic devices such as an FPGA.

There is also a need for accurately and efficiently transmitting data using autoencoder in electronic devices such as an FPGA.

There is also a need for an autonomous system capable of periodically self training to update what it considers non-anomaly background event to be more sensitive to anomalous events in a changing environment.

### SUMMARY OF THE INVENTION

Accordingly, it is an object of the present disclosure to provide a novel system, apparatus, and method for evaluating boosted decision trees (BDT) in an electronic device (programmable or non-programmable), e.g., a Field Programmable Gate Arrays (FPGA), an application specific integrated circuit (ASIC), etc., with typical latency and interval in as low as two clock ticks. The timing values as low as two clock ticks can be less than ten nanoseconds in some systems, and achieved in typical applications. The clock ticks (i.e., a number of operations per second) may be specified by a user and differ according to a type of the electronic device used. The optimization of the BDT configuration after the training step allows low timing values to be achieved for the evaluation step. The present disclosure provides a device, e.g., a software package called fwXmachina, that automates the BDT optimization to lay out the electronics design in firmware. In addition to preparing BDT for FPGA, the embodiments in accordance with the present disclosure provides a number of novel design features for BDT evaluation. In addition, the present disclosures provide a number of novel design features that are relevant in the evaluation of other machine learning algorithms, such as neural networks, for FPGA,

It is also an object of the present disclosure to provide autoencoders using decision tree grid (DTG) for nanosecond anomaly detection and data transmission. The autoencoders in accordance with the present disclosure uses decision trees, not neural networks (as the conventional ML methods do), in order to detect and alert the rare anomalous events at high efficiency (e.g., achieving latency of tens of nanoseconds). Any implementation of decision tree may be used in the autoencoder. However, the autoencoders using decision trees are optimally implemented in the FPGAs with decision paths (DP) to optimize efficiency for such parallel implementation. A DP is a set of comparisons that connect the initial node of the decision tree and a given terminal node. Therefore, there are as many DP as there are terminal nodes in a decision tree. Since the set of DP characterizes all of the possible scenarios of a decision tree, the set can be evaluated in parallel resulting in a one-hot path leading to the terminal bin that the input data belongs to. The DP architecture of the decision tree allows the simultaneous evaluation of all possible paths while maintaining efficiency in implementation on FPGA. Further, the autoencoder may be trained in an unsupervised manner using a one-sample training data, as opposed to supervised ML training using multiple sample training data, e.g., “signal” and “background” samples. The autoencoder may also be used to transmit encoded data efficiently by, e.g., splitting bit engines into an encoding part and a decoding part for transmitting encoded data.

These objects are achieved according to embodiment of the present disclosure by providing a system for providing a boosted decision tree (BDT) for use on an electronic device to provide an event score based on a user input event, where the device includes: a machine learning trainer configured to create a trained BDT from an untrained BDT by determining parameters for the untrained BDT; a nanosecond optimizer configured to create an optimized BDT, the nanosecond optimizer including at least one of a tree flattener configured to flatten a plurality of vertical layers of a decision three into one layer, a tree merger configured to merge a plurality of flattened decision trees into one tree, a score normalizer configured to normalize a score of a bin of a flattened tree, a tree remover configured to remove one or more flattened decision trees in accordance with a user specification, and a cut eraser configured to erase a cut between bins in the flattened tree in accordance with a user specification, and a converter coupled to the nanosecond optimizer and configured to receive the optimized BDT from the nanosecond optimizer and convert the optimized BDT to a language for high-level-synthesis to produce a hardware description language representation of the optimized BDT, wherein the hardware description language representation of the optimized BDT is structured and configured to be implemented in firmware provided on the electronic device to enable the electronic device to determinate and output an event score based on a user input event.

In some examples, the electronic device is a Field Programmable Gate Array. In some examples, the nanosecond execution of machine learning algorithm in the FPGA is performed in as low as two clock ticks, which is less than ten nanoseconds in some systems. In some examples, the nanosecond optimizer eliminates firmware-side multiplications in calculating a weighted average of the event score, thereby reducing latency and increasing efficiency of the system. In some examples, the nanosecond optimizer further comprises a score finder configured to find the event score of the bin of the flattened tree. In some examples, the plurality of data in the lookup table have been pre-evaluated and pre-processed for respective specific needs for the event testing. In some examples, the firmware performs a bit-shift-ready linear piecewise approximation of a nonlinear function within a predefined range. In some examples, the nanosecond optimizer further includes a staircase approximation of diagonal cuts across an n-dimensional gridspace. In some examples, the nanosecond optimizer further includes an axis rotator configured to decompose a rotation of n-dimensional coordinate planes into rotations over a plurality of two-dimensional coordinate planes, In sonic examples, bit-shifting acts as a division operator for divisions requiring a same divisor such that bit-shifting reduces latency and increase efficiency of the system. In some examples, the nanosecond optimizer comprises at least the tree flattener and the forest merger. In some examples, the device further includes a lookup table coupled to the nanosecond optimizer, the lookup table comprising a plurality of data including predefined bin-indexed event scores based on event testing at each node of the flattened decision trees; and a firmware coupled to the converter and the lookup table, the firmware configured to receive the hardware description language, wherein the firmware comprises a bin engine configured to determine a bin index associated with a node of the flattened decision trees via bit shifting or using bin addresses for accessing the lookup table.

Another embodiment in accordance with present disclosure provides a method for providing a boosted decision tree (BDT) for use on an electronic device to provide an event score based on a user input event. The method includes creating a trained BDT from an untrained BDT by determining parameters for the untrained BDT; optimizing the trained BDT using a nanosecond optimizer to create an optimized BDT, the nanosecond optimizer comprising at least one of (i) a tree flattener configured to flatten a plurality of vertical layers of a decision three into one layer, (ii) a forest merger configured to merge a plurality of flattened decision trees into one tree, (iii) a score normalizer configured to normalize an event score of a bin of a flattened tree, (iv) a tree remover configured to remove one or more flattened decision trees in accordance with a user specification, or (v) a cut eraser configured to erase a cut between bins within a flattened decision tree in accordance with the user specification, and receiving the optimized BDT from the nanosecond optimizer and converting the optimized BDT to a language for high-level-synthesis to produce a hardware description language representation of the optimized BDT, wherein the hardware description language representation of the optimized BDT is structured and configured to be implemented in firmware provided on the electronic device to enable the electronic device to determinate and output an event score based on a user input event.

In some examples, the electronic device is a Field Programmable Gate Array. In some examples, the nanosecond execution of machine learning algorithm in the FPGA is performed in as low as two clock ticks, which is less than ten nanoseconds in some systems. In some examples, the nanosecond optimizer eliminates firmware-side multiplications in calculating a weighted average of the event score, thereby reducing latency and increasing efficiency of the system. In some examples, the nanosecond optimizer further comprises a score finder configured to find the event score of the bin of the flattened tree. In some examples, the plurality of data in the lookup table have been pre-evaluated and pre-processed for respective specific needs for the event testing. In some examples, the firmware performs a bit-shift-ready linear piecewise approximation of a nonlinear function within a predefined range. In some examples, the nanosecond optimizer further includes a staircase approximation of diagonal cuts across an n-dimensional gridspace. In some examples, the nanosecond optimizer further includes an axis rotator configured to decompose a rotation of n-dimensional coordinate planes into rotations over a plurality of two-dimensional coordinate planes. In some examples, bit-shifting acts as a division operator for divisions requiring a same divisor such that bit-shifting reduces latency and increase efficiency of the system. In some examples, the nanosecond optimizer comprises at least the tree flattener and the forest merger. In some examples, the device further includes a lookup table coupled to the nanosecond optimizer, the lookup table comprising a plurality of data including predefined bin-indexed event scores based on event testing at each node of the flattened decision trees; and a firmware coupled to the converter and the lookup table, the firmware configured to receive the hardware description language, wherein the firmware comprises a bin engine configured to determine a bin index associated with a node of the flattened decision trees via bit shifting or using bin addresses for accessing the lookup table.

Another embodiment in accordance with the present disclosure provides an electronic device including firmware implementing an optimized boosted decision tree (BDT) generated from an untrained BDT by: creating a trained BDT from the untrained BDT by determining parameters for the untrained BDT, optimizing the trained BDT using a nanosecond optimizer to create an optimized BDT, the nanosecond optimizer comprising at least one of: of (i) a tree flattener configured to flatten a plurality of vertical layers of a decision three into one layer, (ii) a forest merger configured to merge a plurality of flattened decision trees into one tree, (iii) a score normalizer configured to normalize an event score of a bin of a flattened tree, (iv) a tree remover configured to remove one or more flattened decision trees in accordance with a user specification, or (v) a cut eraser configured to erase a cut between bins within a flattened decision tree in accordance with the user specification, and converting the optimized BDT to a language for high-level-synthesis to produce a hardware description language representation of the optimized BDT, wherein the firmware implements the hardware description language representation of the optimized BDT.

Another embodiment in accordance with present disclosure provides a method of determining an event score using a boosted decision tree using a device configured to be implemented in an electronic device for optimizing nanosecond execution of machine learning algorithm. The method includes: receiving an input data for an uncategorized event; determining a bin index associated with the input data by bit-shifting or using bin addresses for accessing a lookup table comprising a plurality of data including predefined bin indices based on event testing; determining an event score associated with the input data; and outputting the event score.

In some examples, the electronic device is a Field Programmable Gate Array. In some examples, the nanosecond execution of machine learning algorithm in the FPGA is performed in as low as two clock ticks. In some examples, the nanosecond optimizer eliminates firmware-side multiplications in calculating a weighted average of the event score. In some examples, the plurality of data in the lookup table have been pre-evaluated and pre-processed for respective specific needs for the event testing at each node of the flattened decision trees. In some examples, the nanosecond optimizer performs a bit-shift-ready linear piecewise approximation of a nonlinear function within a predefined range. In some examples, the nanosecond optimizer further includes a staircase approximation of diagonal cuts across an n-dimensional gridspace. The nanosecond optimizer further comprises an axis rotator configured to decompose a rotation of n-dimensional coordinate planes into rotations over a plurality of two-dimensional coordinate planes. In some examples, bit-shifting acts as a division operator for divisions requiring a same divisor.

Another embodiment in accordance with the present disclosure provides a non-transitory computer-readable medium storing code for nanosecond execution of machine learning algorithm in an electronic device, the code comprising instructions executable by a processor of the electronic device to: a machine learning trainer to receive input training data for determining the parameters of the machine learning algorithm and to provide a tree structure that is more suitable for the electronic device; optimize the parameters and the structure of the trained BDT, wherein the instructions to optimize comprises instructions to: flatten a plurality of vertical layers of a decision three into one layer; merge a plurality of flattened decision trees into one tree; normalize an event score of a bin of a flattened tree and eliminate firmware-side multiplication in calculating a weighted average of an event; remove one or more trees having no effect on event scores of one or more flattened decision trees; or erase a cut having no effect to the event scores of the one or more flattened decision trees; convert the optimized data to a language to use high-level-synthesis language to produce hardware description language for use in the electronic device; determine a bin index associated with the input data; and determine the event score associated with the input data.

Another embodiment in accordance with the present disclosure provides an autoencoder system including an autoencoder configured to receive input data, encode the input data and decode the encoded data using decision tree grid (DTG) where the autoencoder includes a machine learning (ML) trainer configured to determine parameters for the autoencoder and cut thresholds for DTG using an importance trainer to create a trained DTG from an untrained DTG; a nanosecond optimizer comprising a decision path (DP) architecture for creating an optimized DTG by logically flattening a plurality of combinations of comparisons that connect initial node to terminal nodes of the trained DTG into one set of DPs for simultaneous evaluation; a converter coupled to the autoencoder and configured to receive the optimized DTG and convert the optimized DTG to a language for high-level-synthesis to produce a hardware description language of the optimized DTG, where the hardware description language representation of the optimized DTG is structured and configured to be implemented in firmware provided on an electronic device, and where the firmware is configured to receive the hardware description language and comprises (i) a plurality of deep decision tree (DDT) engines configured to receive copies of the input data and evaluate each decision path independently from a plurality of depth associated with a structure of a decision tree; and (ii) a processing portion configured to process outputs from the plurality of deep decision tree engines, the processing portion comprising an estimator configured to reconstruct the input data using the encoded data and a distance determiner configured to determine a distance between the input and the reconstructed data.

In some examples, the distance is indicative of detected anomaly based on a determination that the distance is farther than a distance of reconstructed non-anomaly background event and the detected anomaly is transmitted to a user and stored in memory. In some examples, the distance is indicative of faithful reconstruction of the input data and the autoencoder is further configured to transmit the encoded data by splitting the deep decision tree engines into an encoding part and a decoding part and explicitly introducing the encoded data that are transmitted over a large physical distance by a method of signal transmission. In some examples, the electronic device is a Field Programmable Gate Array. In some examples, the DTG acts as encoder and decoder and performs encoding and decoding simultaneously. In some examples, the autoencoder bypasses production of latent space data. In some examples, the DTG utilizes a deep decision tree engine based on the simultaneous evaluation of the set of decision paths, each decision path localizing the input data according to upper and lower bounds on each input variable. In some examples, the DTG stores information about a terminal leaf of the decision tree in the form of bin indices as the encoded data and does not store a unique score of the terminal leaf. In some examples, the autoencoder is self trained periodically according to user specifications by the importance trainer using one-sample training data in an unsupervised manner by using input data simultaneously stored in memory.

Another embodiment in accordance with the present disclosure provides a method for nanosecond execution of an autoencoder with a decision tree grid (DTG). The method includes creating a trained DTG from an untrained DTG by determining parameters for an autoencoder and cut thresholds for the DTG, creating an optimized DTG by logically flattening a plurality of combinations of comparisons that connect initial nodes to terminal nodes of the trained DTG into one set of decision paths (DPs) for simultaneous evaluation, converting the optimized DTG to a language for high-level-synthesis to produce a hardware description language representation of the optimized DTG, wherein the hardware description language representation of the optimized DTG is structured and configured to be implemented in firmware provided on an electronic device, and wherein the firmware is configured to receive the hardware description language representation and includes a plurality of deep decision tree engines configured to receive copies of the input data and evaluating each decision path independently from a plurality of depths associated with a structure of a decision tree, and a processing portion configured to process outputs from the plurality of deep decision tree engines, wherein the processing portion includes an estimator configured to reconstruct the input data using the encoded data and a distance determiner configured to determine a distance between the input and the reconstructed data.

In some examples, the distance is indicative of detected anomaly based on a determination that the distance is farther than a distance of reconstructed non-anomaly background event and the detected anomaly is transmitted to a user and stored in memory. In some examples, the distance is indicative of faithful reconstruction of the input data and the autoencoder is further configured to transmit the encoded data by splitting the bin engines into an encoding part and a decoding part and explicitly introducing the encoded data that are transmitted over a large physical distance by a method of signal transmission. In some examples, the electronic device is a Field Programmable Gate Array. In some examples, the DTG acts as encoder and decoder and performs encoding and decoding simultaneously, and the autoencoder bypasses production of latent space data. In some examples, the DTG utilizes a deep decision tree engine based on the simultaneous evaluation of the one set of decision paths, each decision path localizing the input data according to upper and lower bounds on each input variable. In some examples, the DTG stores information about a terminal leaf of the decision tree in the form of bin indices as the encoded data and does not store a unique score of the terminal leaf. In some examples, the autoencoder is self-trained periodically according to user specifications by the importance trainer using one-sample training data in an unsupervised manner by using the input data simultaneously stored in memory.

Another embodiment in accordance with the present disclosure provides an electronic device including firmware implementing an optimized decision tree grid (DTG) generated from an untrained DTG by: creating a trained DTG from an untrained DTG by determining parameters for an autoencoder and cut thresholds for the DTG; creating an optimized DTG by logically flattening a plurality of combinations of comparisons that connect initial nodes to terminal nodes of the trained DTG into one set of DPs for simultaneous evaluation; converting the optimized DTG to a language for high-level-synthesis to produce a hardware description language representation of the optimized DTG, wherein the hardware description language representation of the optimized DTG is structured and configured to be implemented in firmware provided on an electronic device and where the firmware includes (i) a plurality of deep decision tree (DDT) engines configured to receive copies of the input data and evaluate each decision path independently from a plurality of depths associated with a structure of a decision tree, and (ii) a processing portion configured to process outputs from the plurality of deep decision tree engines, the processing portion comprising an estimator configured to reconstruct the input data using the encoded data and a distance determiner configured to determine a distance between the input and the reconstructed data.

Another embodiment in accordance with the present disclosure provides a method of nanosecond execution of an autoencoder with a decision tree grid (DTG). The autoencoder and a firmware including deep decision tree engines are coupled to an electronic device for implementation. The method includes receiving an input data for an uncategorized event; optimizing the DTG by flattening a plurality of depth associated with the structure of a decision tree into one set of combinations comprising one DP for simultaneous evaluation; encoding the input data and decoding the encoded data; reconstructing the input data using the encoded data; and obtaining a distance between the input data and the reconstructed data.

In some examples, the method also includes transmitting detected anomaly to a user, where the encoding the input data and the decoding the encoded data occur simultaneously and the distance is indicative of detected anomaly based on a determination that the distance is higher than a distance of reconstructed non-anomaly background event; and storing the detected anomaly and information associated with the detected anomaly in memory. In some examples, the method further includes transmitting the encoded data by splitting the deep decision tree engine into an encoding part and a decoding part and explicitly introducing the encoded data for transmission over a large physical distance by a method of signal transmission, where the distance is indicative of faithful reconstruction of the input data, and storing at least the input data and the encoded data in memory. In some examples, the autoencoder is implemented in a Field Programmable Gate Array. In some examples, the method also includes the DTG acts as encoder and decoder and performs encoding and decoding simultaneously. In some examples, the autoencoder is self-trained continuously using one-sample data by importance trainer configured to optimize cut thresholds for reconstruction of non-anomaly background event and minimize a distance of training sample for a variable being considered. In some examples, the distance indicates an anomalous deviation from the non-anomaly background event. In some examples, the method further includes transmitting, by the autoencoder, the encoded data by splitting the deep decision tree engine into an encoding part and a decoding part and explicitly introducing the encoded data for transmission over a large physical distance by a method of signal transmission.

These and other objects; features, and characteristics of the present invention, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

### BRIEF DESCRIPTION OF THE DRAWINGS

FIG. 1 illustrates a system for nanosecond execution of machine learning algorithm according to one particular, non-limiting exemplary embodiment of the disclosed concept;

FIG. 2 is a block diagram of a nanosecond optimization framework according to one particular, non-limiting exemplary embodiment, including the various components housed therein;

FIG. 3 is a conventional decision tree;

FIGS. 4A-B illustrate a bin engine using bit-shifting according to one particular, non-limiting exemplary embodiment of the disclosed concept;

FIG. 5 is a schematic block diagram of a bin engine using addresses according to one particular, non-limiting exemplary embodiment of the disclosed concept;

FIGS. 6A-B illustrates tree flattening according to one particular, non-limiting exemplary embodiment of the disclosed concept;

FIG. 7 illustrates forest merging according to one particular, non-limiting exemplary embodiment of the disclosed concept;

FIG. 8 illustrate a binary binning strategy according to one particular, non-limiting exemplary embodiment of the disclosed concept;

FIG. 9 is diagram of staircase method for angled cut application according to one particular, non-limiting exemplary embodiment of the disclosed concept;

FIGS. 10-B shows graphs of piecewise approximation according to one particular, non-limiting exemplary embodiment of the disclosed concept;

FIG. 11 illustrate cut-removing according to one particular, non-limiting exemplary embodiment of the disclosed concept;

FIG. 12 illustrates a score finder according to one particular, non-limiting exemplary embodiment of the disclosed concept;

FIG. 13 illustrates bin erasing according to one particular, non-limiting exemplary embodiment of the disclosed concept;

FIG. 14 is a schematic block diagram of an evaluation processor according to one particular, non-limiting exemplary embodiment of the disclosed concept;

FIG. 15 is a flowchart for a method of determining event scores according to one particular, non-limiting exemplary embodiment of the disclosed concept;

FIG. 16 is an autoencoder system for nanosecond anomaly detection or data transmission according to one particular, non-limiting exemplary embodiment of the disclosed concept;

FIG. 17 is a block diagram of a framework of the autoencoder system according to one particular, non-limiting exemplary embodiment of the disclosed concept;

FIGS. 18A-B illustrate autoencoder concepts, including two use cases of a conventional autoencoder;

FIGS. 19A-B illustrate a deep decision tree (DDT) autoencoder for use in a field programmable gate array (FPGA) according to one particular, non-limiting exemplary embodiment of the disclosed concept;

FIGS. 20A-C illustrate simultaneous encoding and decoding using a DDT autoencoder according to one particular, non-limiting exemplary embodiment of the disclosed concept;

FIGS. 21-23 depict distance estimations by a DDT autoencoder according to one particular, non-limiting exemplary embodiment of the disclosed concept;

FIGS. 24A-E illustrate ML training of deep decision tree (DDT) on decision tree grid (DTG) according to one particular, non-limiting exemplary embodiment of the disclosed concept;

FIGS. 25 illustrates anomaly score distributions according to one particular, non-limiting exemplary embodiment of the disclosed concept;

FIG. 26 illustrates nanosecond data-transmission of encoded data using a DDT autoencoder according to one particular, non-limiting exemplary embodiment of the disclosed concept;

FIG. 27 illustrates a DDT autoencoder configured to perform continuous self-aware ML training according to one particular, non-limiting exemplary embodiment of the disclosed concept;

FIG. 28 is a flow chart for a method for providing a boosted decision tree (BDT) for use on an electronic device to provide an event score based on a user input event according to one particular, non-limiting exemplary embodiment of the disclosed concept;

FIG. 29 is a flow chart for a method of nanosecond anomaly detection using an autoencoder with a decision tree grid (DTG) according to one particular, non-limiting exemplary embodiment of the disclosed concept;

FIG. 30 is a flow chart for a method of nanosecond data transmission using an autoencoder with a decision tree grid (DTG) according to one particular, non-limiting exemplary embodiment of the disclosed concept; and

FIG. 31 is a flow chart for a method of for nanosecond execution of an autoencoder with a decision tree grid (DTG) according to one particular, non-limiting exemplary embodiment of the disclosed concept.

### DETAILED DESCRIPTION OF EXEMPLARY EMBODIMENTS

As used herein, the singular form of “a”, “an”, and “the” include plural references unless the context clearly dictates otherwise.

As used herein, the statement that two or more parts or components are “coupled” shall mean that the parts are joined or operate together either directly or indirectly, i.e., through one or more intermediate parts or components, so long as a link occurs.

As used herein, “directly coupled” means that two elements are directly in contact with each other.

As used herein, the term “number” shall mean one or an integer greater than one (i.e., a plurality).

Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

The disclosed concept will now be described, for purposes of explanation, in connection with numerous specific details in order to provide a thorough understanding of the subject innovation. It will be evident, however, that the disclosed concept can be practiced without these specific details without departing from the spirit and scope of this innovation.

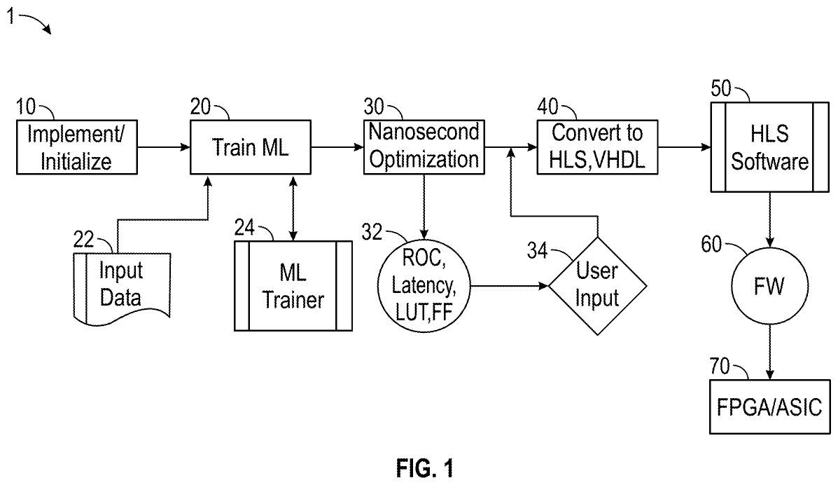

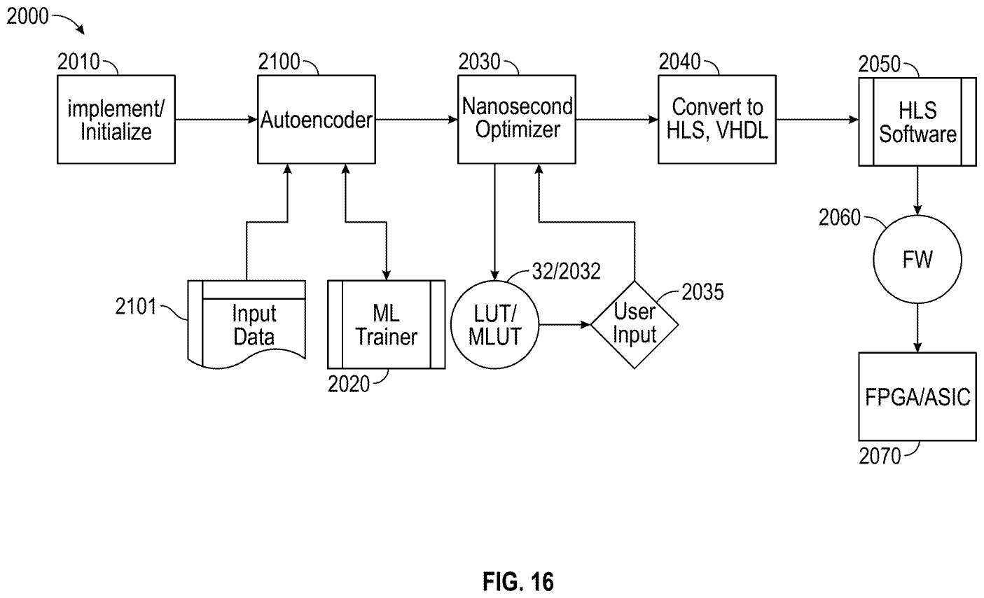

FIGS. 1-15 illustrate a system, apparatus, and method for nanosecond execution of Machine Learning algorithm for event classification using boosted decision trees (BDT) in a Field Programmable Gate Arrays (FPGA). FIGS. 16-30 illustrate a system, apparatus, and method for nanosecond anomaly detection and/or encoded data transmission using autoencoders with decision tree grid in an FPGA.

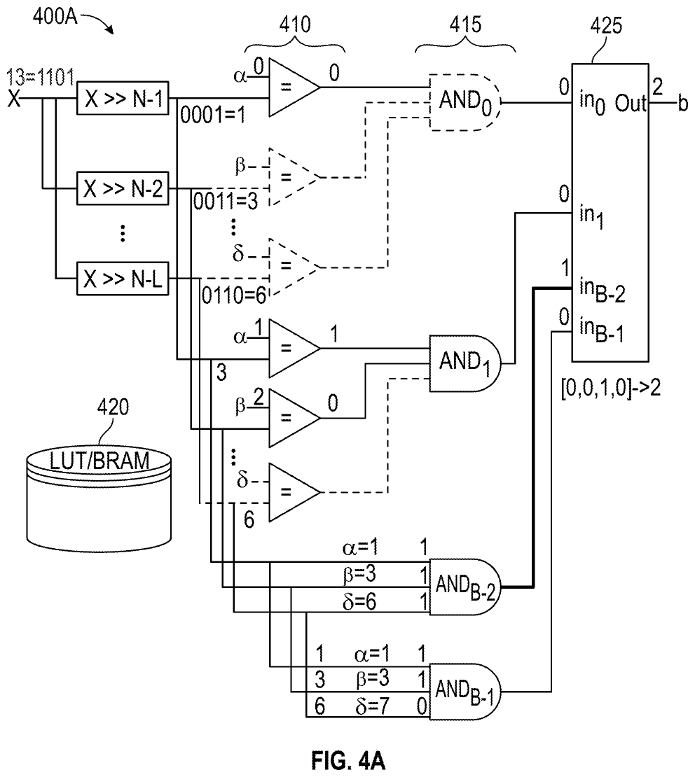

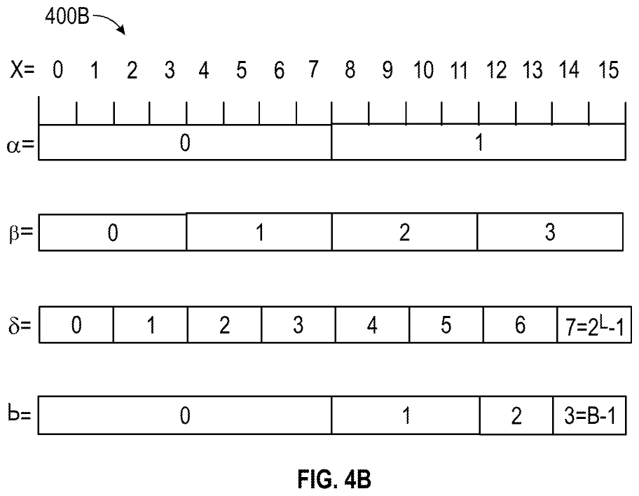

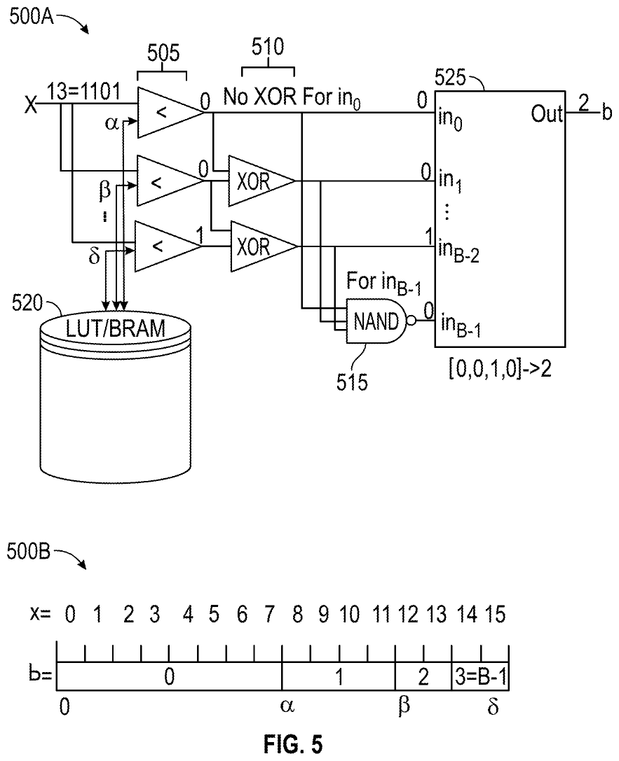

FIG. 1 is a system 1 for determining an event score using a boosted decision tree according to one particular, non-limiting exemplary embodiment of the disclosed concept. The system 1 includes a device 10 configured to optimize machine learning algorithm execution, a firmware 60 coupled to the device 10, and an electronic device configured to implement the firmware 60. The device 10 may be a software (e.g., fwXmachina) and include a ML training component 20, a table of characteristics 32, a nanosecond optimizer 30, and an HLS converter 40. The firmware 60 is configured to implement the converted optimized BDT via the HLS/VHDL software 50 for use in an electronic device 70, e.g., FPGA. The firmware 60 includes a bin engine (as shown in FIGS. 4A and 5) configured to determine a bin index associated with a node of the flattened decision trees by bit-shifting or using bin addresses for accessing the lookup table 520 (as shown in FIG. 5). The lookup table 520 may include the plurality of data that have been pre-evaluated and pre-processed for respective specific needs for the event testing. The firmware 60 may be implemented in the electronic device 70 configured to determine and output an event score of a user input event. The electronic device 70 may be a field programmable gate array, an electronic switch, an application-specific integrated circuit (ASW)).

Generally speaking, the system 1 receives a user input, determines which bin the input should be placed, and determines whether the input is a signal, a background, or the probability of signal and background as low as two clock ticks, which is less than 10 nanoseconds in some systems, using various mechanisms using the mechanisms and devices described herein. The present disclosure describes novel concepts that may pertain to general machine learning or artificial intelligence (hereinafter, referred to as “ML”) algorithms, specific algorithms associated with the boosted decision trees (BDT), and specific algorithms with other more specific ML algorithms (e.g., piecewise approximation, staircase method, cut remover, etc.) as described with respect to each of feature of the system 1. As such, the embodiments in accordance with the present disclosure not only utilize tools, e.g., neural networks, that are commonly useful for classification problems in general or to group of ML algorithms, but also include novel tools that are specifically designed to solve problems in implementing BDT.

The novelties associated with general ML algorithms include elimination of multiplication in firmware, score pre-processing using bin-based ML, and binning by, bit-shift. Multiplication is very resource-intensive, and thus, by eliminating multiplication the present disclosure allows low resource usage and latency in firmware FPGA applications. Implementing score pre-processing in FPGA using bin-based ML is novel. In triggering applications, the algorithms generally focus on whether an event passes or not. Machine learning algorithms often return more precise values corresponding to probabilities. By rounding the bin values to ±1 in advance, the embodiments in accordance with the present disclosure save a clock tick on the firmware by simply returning a pass/fail value rather than a needlessly precise one. Binning by bit-shift is novel. A determination on a bin location of an incoming coordinate may be made by simultaneous integer division by pre-determined divisors. In other words, a bin may be decomposed into several layers of grids, which are bin spaces with equally spaced bins, each with a different number of cuts. Evaluating the coordinate location in each of the several grids is much less effort, especially when the division required to map the coordinate to the grids is a power of two, as bit-shifting may then be used.

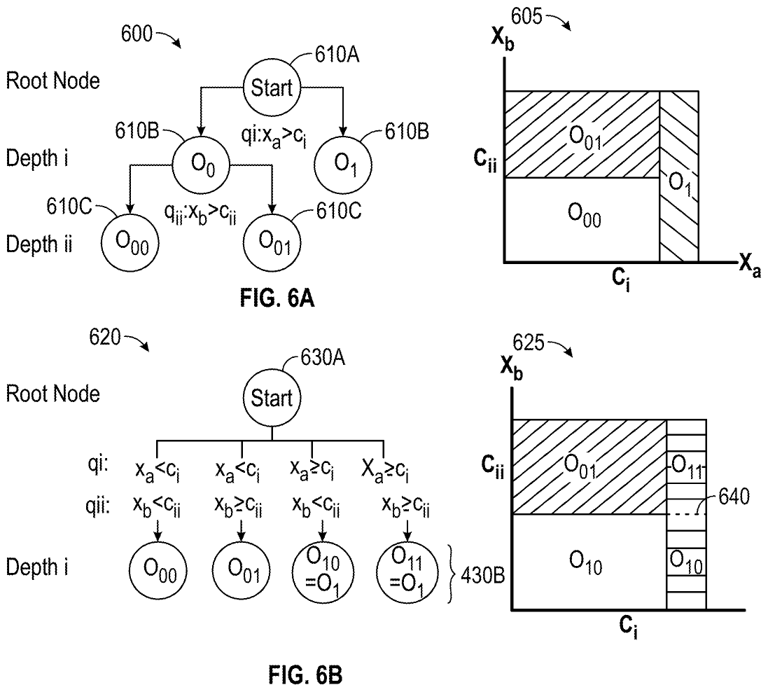

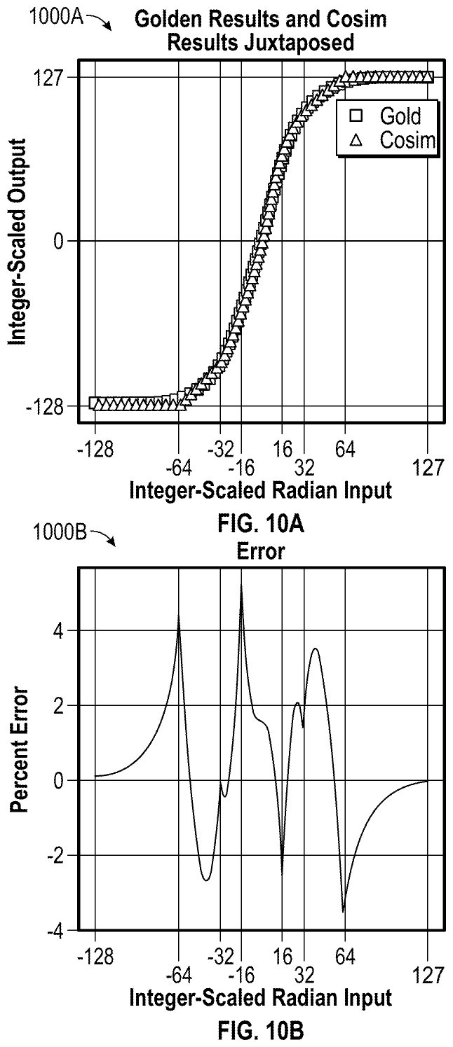

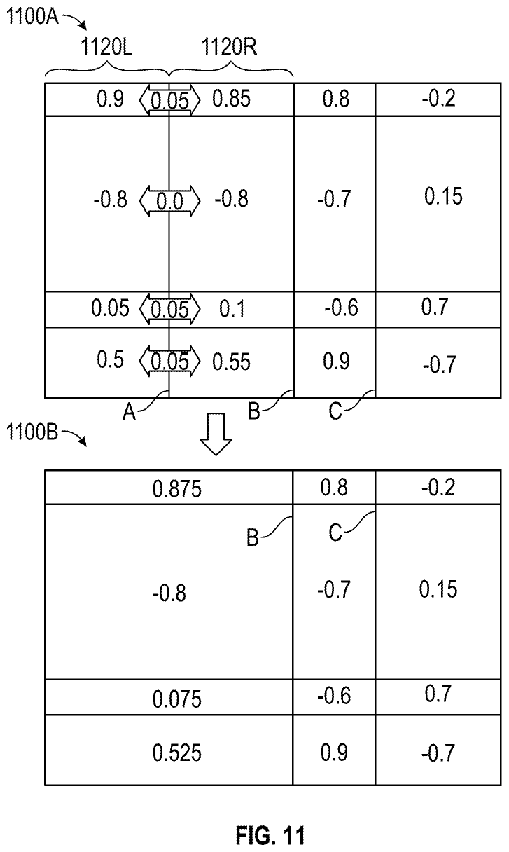

The novelties associated with BDT-specific algorithms include tree flattener (e.g., as shown in FIGS. 6A-B), forest merger (e.g., as shown in FIG. 6), score normalizer (e.g., a piecewise approximator of hyperbolic tangent as shown in FIG. 10A), a bit-shift-ready linear piecewise approximator (as described below), tree remover (as described below), and cut eraser (e.g., a cut remover as shown in FIG. 11). Score normalization eliminates the need for firmware-side multiplication in calculating the weighted average of an event by weighting scores of a tree's bin to the boost-weight divided by the sum of the boost-weights. Applying tree flattening and forest merging to FPGAs is novel. A bit-shift-ready linear piecewise approximation and implementation of bit-shifting in piecewise approximation in firmware are novel. Removing trees that have no impact on the score of a tree's bin, and removing a cut that has no effect is novel.

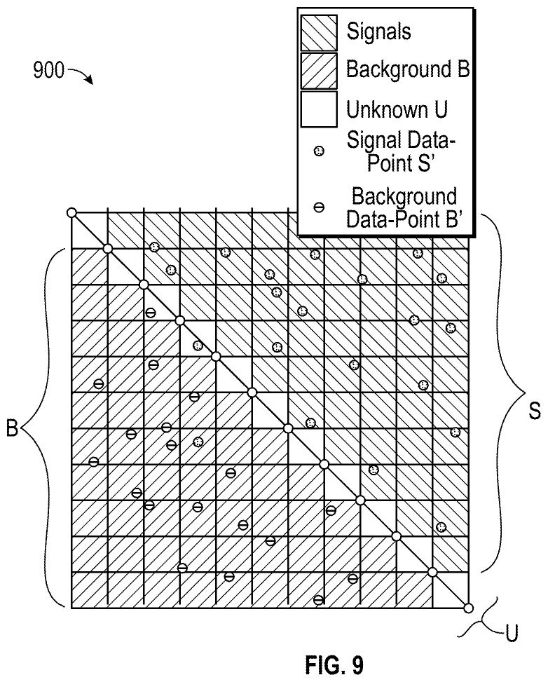

The novelties associated with algorithms specific to other ML methods include staircase method (e.g., a staircase method as shown in FIG. 9) and variable axis rotation (as described below). The staircase method approximates diagonal cut across an n-dimensional gridspace with a bin-based approximation. In two dimensions, such approximation resembles a staircase, Variable axis rotation by decomposing a rotation of n-dimensional coordinate planes into rotations over several 2-dimensional coordinate planes is novel. Optimizations may be made for implementation in firmware.

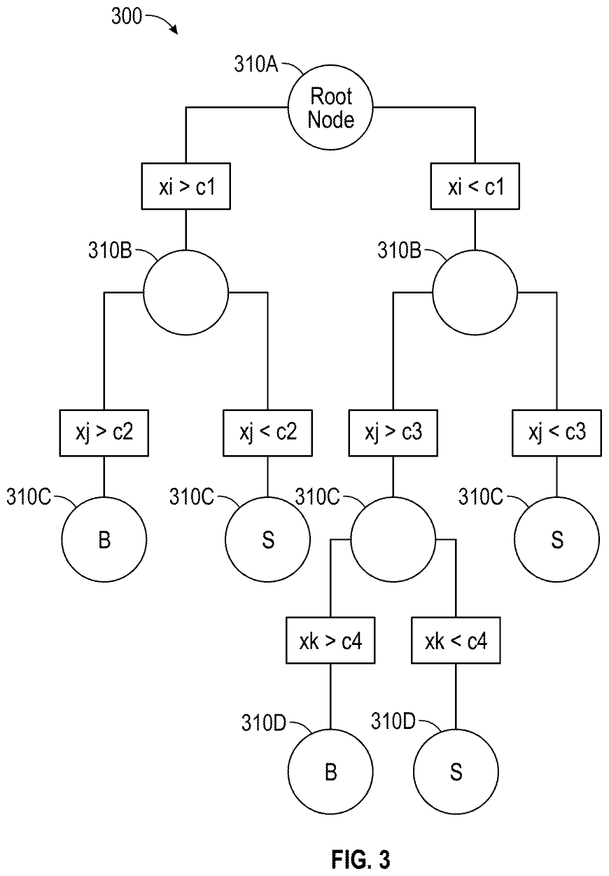

For example, the embodiments in accordance with the present disclosure may utilize adaptive boost in tree merging, so as to reduce multiplication in firmware. A conventional decision tree is shown in FIG. 3. Through “boosting”, multiple trees may be used to evaluate an event where each tree has a boost-weight, and the weighted average of all the trees' outcomes define the event's final score. In an example in which there is a forest of four boosted decision trees, T₁, T₂, T₃, T₄ having boost-weights W₁, W₂, W₃, W₄, respectively, a score O_{T} for each tree may be found (e.g., O₁, O₂, O₃, O₄ for trees , T₁, T₂, T₃, T₄, respectively) when an arbitrary event is pass through the trees. The forest may assign the event a score of:

O_{T}=(O₁W₁+O₂W₂+O₃W₃+O₄W₄)/(W₁+W₂+W₃+W₄) EQ. 1

where the general form of this equation is:

$${O}_{T} = \frac{{\sum }_{i} {O}_{i} {W}_{i}}{{\sum }_{i = 1}^{′} {W}_{i}^{′}} \qquad EQ . 2$$

In hardware, in order to avoid resource-intensive processes such as multiplication and division, the embodiments in accordance with the present disclosure utilize an equivalent form of:

$${O}_{T} = {\sum }_{i} \frac{{O}_{i} {W}_{i}}{{\sum }_{i} , {W}_{i}} , \qquad EQ . 3$$

The normalized score αᵢ may be defined as:

$${{α}_{i}}^{=} \frac{{O}_{i} {W}_{i}}{{Σ}_{i} , {W}_{i}} , \qquad EQ . 4$$

This value may be pre-calculated, e.g., using software, for each bin for each tree and the hardware values of a may be fed. As such, when given an event, the hardware may simply pick the correct bin for each tree, find the αᵢ associated with that bin via a look-up table (LUT), and sum those values for all trees as follows:

O_{T}=Σᵢαᵢ EQ. 5

Thus, the embodiments in accordance with the present disclosure avoid resource-intensive multiplications and divisions, thereby saving resources and time in calculating the desired values.

In some examples, YesNoLeaf may be used. When using YesNoLeaf, at the end of every tree will be a +1 for signal or −1 for background, the final score ranging from −1 to 1. When using purity:

$$P = \frac{S}{S + B} \qquad EQ . 6$$

where P refers to purity, S refers to signal, and B refers to background, and the output is bounded between 0 and 1. In some examples, the embodiments may utilize gradient boost, which makes use of internal regression trees, etc. In those examples, each tree may produce a response, and the score of the tree may be calculated by summing the responses from all the trees, producing response values between −∞and ∞:

γ=Σᵢ₌₀^{#trees}Oᵢ EQ. 7

where γ refers to responses. The response may be then converted to a value between −1 and 1:

$${O}_{T} = tanh γ = \frac{2}{1 + {e}^{- 2 γ}} - 1 \qquad EQ . 8$$

Here, the boost-weights may not matter so that the trees may be easily merged. They may also easily be summed on the firmware. The only resource-intensive step on the firmware may be the final conversion (EQ. 8). This method may be best used when merging all the trees, so that this conversion is done by, e.g., the software. In some examples, the YesNoLeaf and Purity may be irrelevant for this boosting algorithm.

In multiclassification, the classifier may be tasked with discrimination between n potential classes, rather than just two as in the binary cases. The goal of analyzing a point is not to find a score between −1 and 1, but to find a probability between 0 and 1 for each possible “class” into which the data-point could be classified. These probabilities may sum to 1. The data-point is classified by picking class with the highest probability. Each tree in the classification forest is assigned to one of the classes. Recursing down may yield an unbounded response value. When evaluating an event, the first step is that each class gets assigned a preliminary value β by summing the result from all the trees in the forest that belong to that class. For example, for class C₀.

β₀=Σ_{forest}_{ₒ}res EQ. 9

In general, this becomes

βₘ=Σ_{forest}_{ₘ}res EQ. 10

where m is an integer. As such, each class Cₘ has an associated value of βₘ, and in order to use this in obtaining a value for Oₘ, the output score for that class for this event, the “softmax” function to the vector z may be applied as follows:

$${O ( z )}_{i} = \frac{{e}^{{z}_{i}}}{{\sum }_{j = i}^{k} {e}^{{z}_{j}}} for i = 1 , … , k and z = ( {z}_{1} , … , {z}_{k} ) ϵ {R}^{k} \qquad EQ . 11$$

This may return a probability for each class based on the summed response values. The softmax may be applied to the entire vector input. In a 3-class example, assuming that summing the response values of classes, A, B, and C yields values β_{A}=0.4, β_{B}=1.1, β_{c}=−0.4, the application of softmax function results as Softmax({0.4, 1.1, −0.4})={0.289, 0.581, 0.130} for a 28.9% chance that the event in question belongs to class A, a 58.1% chance it belongs to class B, and 13.0% chance it belongs to class C. However, softmax need not be applied to obtain the class with the highest probability since the class with the highest summed response score will have the highest probability. In the preceding example, it would he discernable that class B is the most likely of the three without applying softmax since 1.1>0.4>−0.4.

The embodiments in accordance with the present disclosure may convert arrays of cuts, intermediates, and scores to integers of variable bit precision in order to improve firmware performance. The range of the variables may be between 0 and 2^{bits}—1. For example, when using 10-bit integers, that provide 2¹⁰=1024 possibilities, or values ranging from 0-1023. To convert arrays from floating point to integer precision, first, a maximum and minimum are identified. Sometimes, these may simply be the maximum and minimum of the array, but other times it will be determined by other values. In the case of cut locations, the range of possible values that variable can attain may determine the maximum and minimum. A resolution may be defined by dividing the range of the floating point data by the number of points possible:

$$resolution = \frac{range}{n Points} = \frac{max - min}{{2}^{bits} - 1} \qquad EQ . 12$$

The array of floating point digits is converted to bit integers by shifting them by the minimum and dividing by the resolution. Every point in the array has the following formula applied:

$$int = floor [ \frac{float - min}{resolution} ] \qquad EQ . 13$$

This is a linear transformation if and only if min=0, meaning that we cannot perform operations on these results since non-linear transformations do not preserve addition or scalar multiplication. For example, where constants

$$m = \frac{1}{resolution} and b = \frac{min}{resolution} ,$$

this transformation is of the form T(x)=mx+b. It can be proven that this is only a linear transformation when b=0, since T(x₁+x₂) ≠T(x₁)+T(x₂) otherwise. That is, assuming that T(x₁+x₂)=T(x₁)+T(x₂), then T(x₁)=mx₁+b and T(x₂)=mx₂+b, and T(x₁+x₂)=m (x₁+x₂)+b=mx₁+mx₂+b. Therefore, T(x₁+x₂)=T(x₁)+T(x₂) implies that mx₁+mx₂+2b=mx₁+mx₂+b. Thus, 2b=b, and thus, b=0. Therefore, it is proven that T is a linear transformation if an only if b=0, and thus, the transformation (EQ. 13) is only linear when min−0. This may imply that once the arrays of cuts, intermediate, and scores have been converted to integers, operations such as addition or multiplication may not be performed without getting false results. However, the normalized scores need be added in the firmware. It is noted that, using purity (from EQ. 6) as the metric, min=0 where the scores range from 0 to 1 as floating point values, and this is a linear transformation. However, when we use YesNoLeaf the scores range from −1 to 1, the transformation

$$int = \frac{float}{resolution} \qquad ( EQ . 14 )$$

is applied. By removing the constant shift by a factor of min, it becomes a linear transformation of the form T(x)=mx where

$$m = \frac{1}{resolution} .$$

### Here

$$resolution = \frac{max - 0}{{2}^{bits} - 1}$$

where max is 1.0. Thus, the transformation under the present disclosure simplifies to int=(float)(2^{bits}−1), and a value between [-(2^{bits}−1), 2^{bits}−1] is obtained. The cost of preserving addition and multiplication, however, is one more bit the plus or minus sign. Thus, when 10 bits are specified, a value from −1023 to 1023 results, technically 11 bits.

The embodiments in accordance with the present disclosure utilize a straightforward binning algorithm. An event defined by a value in each variable examined is taken. In each variable, the cuts are scanned over until what two cuts the event falls between are determined, which indicates the “index” of the event in that dimension. Each variable is done in parallel on the FPGA. Knowing the index in each dimension, the index is mapped to the score stored in the proper bin, and the score is returned. The present disclosure provides binary binning (gridification) through bit-shifting. Binary bit-shifting is a very fast way of navigating a grid-space, but it requires that cuts be multiples of two away from each other. Recognizing a tendency for many cuts to be clustered together at regions in the BDT with sensitive changes, the embodiments of present disclosure utilizes optimization called binary gridification. In binary gridification, a user picks a value n, and in each variable, the full range is examined. If n cuts (as floats) fall within that range, the range is split is half, and each half is examined. Cutting ranges in half continues until either there are no longer n cuts in a subrange left or the number of specified bits is reached as shown in the following pseudocode:

```
for each variable:
  take the full range of the variable
  find the number of floating point cuts that fall within that range
  if nCuts > some number (user set):
    divide range in half
    for each half:
      recursively repeat, starting at “find the number...”
      stop once nCuts <= number of cuts required to continue recursion
or
        once you've done this nBits number of times
```

The final results give high precision where many floating point cuts were clustered together, and low precision where floating point cuts were spread out. By splitting the range in half each time, a binary tree has been essentially reformed. This is true, with two significant differences. First, the binary decision trees use any number of variables in a single tree. This binning method produces a single tree for each dimension. Second, in a binary decision tree, if/then statements are used to recurse down the tree. Here, since multiples of two and bit integers are utilized, binary bit-shifting can be used—which is much faster on firmware to recurse down the tree. These trees are traveled down in parallel in each dimension to return the bin index to find the score for an event. Work is being done to explore the notion of representing the relationship between the main bins and different layers of grids as a signal decomposed into a Fourier series, where the frequency represents the number of bins in a certain grid layer.

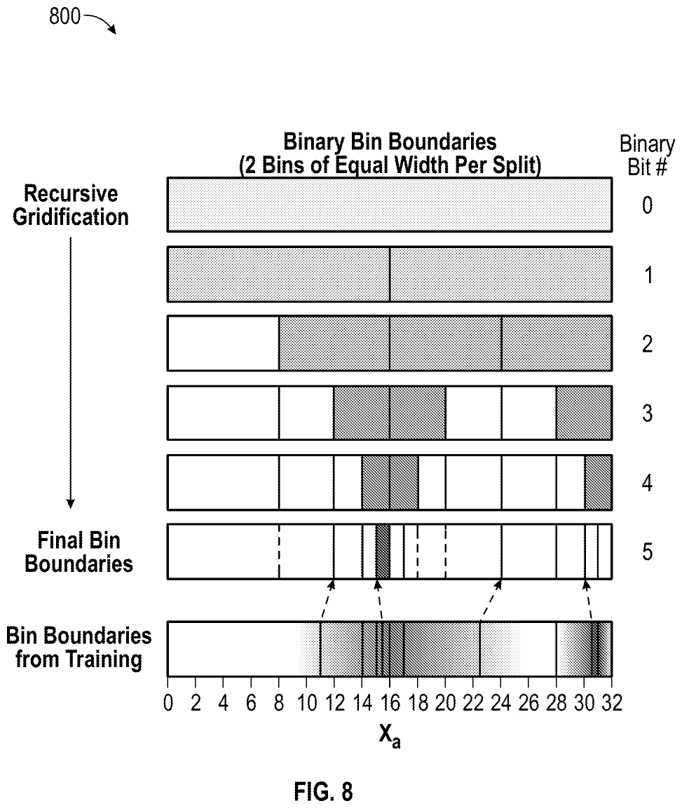

The embodiments in accordance with the present disclosure may also utilize binary binning, i.e., gridification, through bit-shifting (e.g., as shown in FIG. 8). Bit-shifting is a technique used to compute division operations quickly. This operation in computer engineering is known as arithmetic shift right (ASR), but the term “bit-shift” is used throughout the present disclosure for simplicity. Normally, integer division involves a large circuit that will introduce a lot of propagation delay. If the required division is always by the same divisor, then the operation can be instantiated with a faster circuit. The problem can be further optimized when dividing by a power of 2. in base-10 arithmetic, integer-dividing a number by 10 is equivalent to discarding the least significant digit. This heuristic can also be applied to base-2 arithmetic, where a division by 2 is equivalent to removing the least significant bit. This can be realized in hardware by simply disregarding the = least significant bits in a bus, where = is the power of 2 by which the number is being divided.

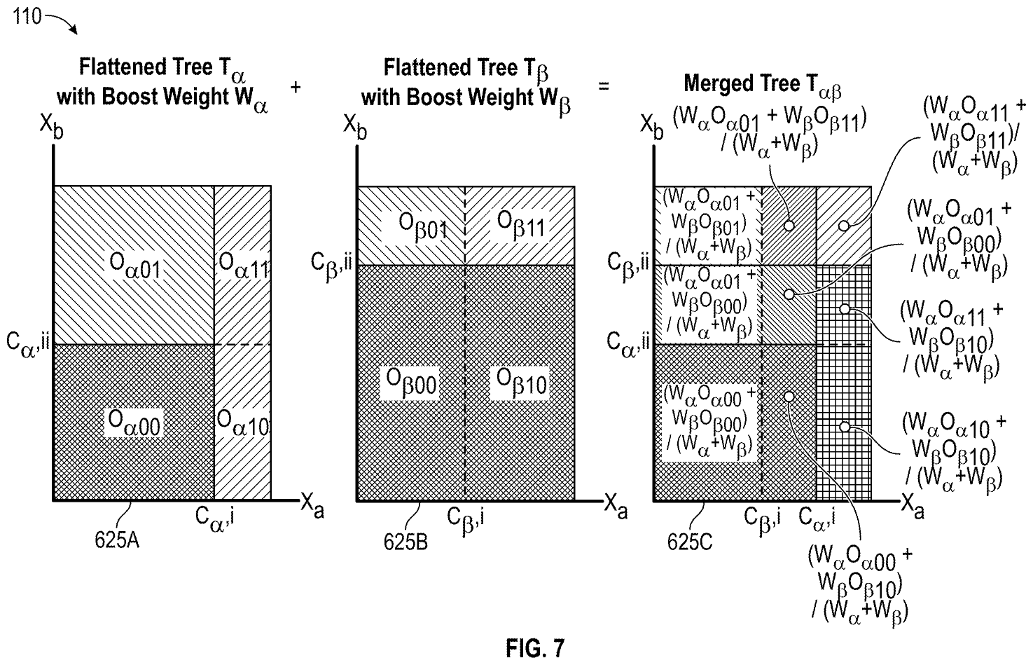

The embodiments in accordance with the present disclosure may also utilize staircase method for Angled Cut Approximation (as shown in FIG. 9). The staircase method may use a linear Fisher discriminant in two-dimensions as discussed further with reference to FIG. 7. In addition, the embodiments may apply various axis rotation in the firmware. Rotating the reference frame by which incoming points are viewed can significantly reduce the complexity of scoring decision in ML. For example, the data for signal and background may be best bisected by a line, plane, hyperplane, etc. These bisecting objects may have nontrivial equations that will require approximation in firmware. If bins are used at this point, the line can only be approximated step-wise. If the bisecting object (and consequently all incoming event coordinates by the same rotation) is rotated to be constant in one dimension (i.e. m−1 degrees of freedom, where m is the number of dimensions) then a decision can be made with a single constant comparison. This is favorably-conditioned especially for embedded systems. In the case of 2D, this can be accomplished with the ubiquitous rotation matrix:

$$R = [ \begin{matrix}cos θ & - sin θ \\ sin θ & cos θ\end{matrix} ] \qquad EQ . 15$$

where θ is the angle between the corresponding axes in each reference frame. The equation applied to each input event vector is:

\vec{P}_{D}=R\vec{P}_{I} EQ. 16

where \vec{P}_{D} is the event's coordinates in the decision space and \vec{P}_{I} is the event's coordinates in the input space. The decision line is implicitly rotated as well and is now a single constant comparison (a.k.a one cut) in the X-axis, independent of the Y-coordinate. When increasing the number of dimensions (i.e., number of ML variables), an iterative process can be used. Treating a pair of axes as its own independent 2D space, the angle between the axes can be taken and the transformation can be applied. A new pair of axes can be then chosen, the next angle can be taken, and the next transformation can be applied. In total, m−1 transformation will be computed, where m is the number of dimensions. Care must be taken to take the angle for each iteration after the previous iteration has been finished, since the rotations are non-commutative. The pair of axes should always include the axis upon which the constant comparison is wished to be made (i.e., in [symbol] , if a decision on X is desired, the planes should be XY and XZ in either order).

Since the angle(s) of rotation is an output from training, and trigonometric functions are deterministic, the values in the rotation matrix can be pre-evaluated:

$$R = [ \begin{matrix}{c}_{x y} & - {s}_{xy} \\ {s}_{xy} & {c}_{x y}\end{matrix} ] \qquad EQ . 17$$

where c_{xy} and s_{xy} are the pre-evaluated values of cos θ_{xy} and sin θ_{xy}, respectively and θ_{xy} is the angle between corresponding axes in the XY plane. A change can also be made to allow for integer arithmetic, which is highly preferable on FPGA architecture. The matrix for integer multiplication is:

$$\overline{R} = [ \begin{matrix}{\overline{C}}_{x y} & - {\overline{S}}_{xy} \\ {\overline{S}}_{xy} & {\overline{C}}_{x y}\end{matrix} ] \qquad EQ . 18$$

where C̅_{xy}=c_{xy}2ⁿ⁻¹ and S̅_{xy}=s_{xy}2ⁿ⁻¹ and n is the number of bits in the signed integer used to represent the data. C̅_{xy} and S̅_{xy} are now integer constants that can be written literally in firmware code. The result of the multiplication between this matrix and the input event coordinates is a vector of 2n-1 bit signed integers. This can be rescaled with the following:

x̅=X̅//2ⁿ⁻¹ and y̅=Y̅//2ⁿ⁻¹ EQ. 19

where X̅ and Y̅ are the members of the vector that describe the rotated position of the event in 2ⁿ⁻¹ bit precision, x̅ and y̅ are the same meaning in n bit precision, and // is the integer division operator. Since the division is a power of 2, bit-shifting can be used instead to decrease operation complexity:

x̅=X̅>>(n−1) and y̅=Y̅>>(n−1) EQ. 20

The final integer arithmetic equation becomes:

\vec{P}_{D}=(R\vec{P}_{I})>>(n−1) EQ. 19

where \vec{P}_{I} and \vec{P}_{D} are the n-bit integer representations of the event in the input domain and the decision domain, respectively.

Most nonlinear functions are either costly or impossible to implement with exact arithmetic on firmware. As such, piecewise approximation is a useful beginning calculating within an acceptable error, but is still ill-conditioned in that it requires multiplication and division for calculating slope. Formally speaking, a piecewise interpolator has nodes that are defined values for the function being approximated. This can be problematic for many functions, as operations with these irrational coefficients for what cause the ill-condition. If nodes are chosen such that the function can be approximated by a rational value, and the slope between the nodes is a power of 2, then the ill-conditioned operations can be removed by replacing them with bit-shifting. Hyperbolic tangent is a nonlinear function that is bounded in the range [−1, 1]. It is an expensive function in both time and area to instantiate on FPGA architecture. In order to approximate the function, the following linear piecewise equation may be used:

$$s ( x ) = \{ \begin{matrix}- 1 , x < - 2 \\ \frac{1}{4} x - \frac{1}{2} , - 2 \leq x < - 1 \\ \frac{1}{2} x - \frac{1}{4} , - 1 \leq x < - \frac{1}{2} \\ x , - \frac{1}{2} \leq x \leq \frac{1}{2} \\ \frac{1}{2} x + \frac{1}{4} , \frac{1}{2} \leq x < 1 \\ \frac{1}{4} x + \frac{1}{2} , 1 \leq x < 2 \\ 1 , 2 < x\end{matrix} \qquad EQ . 22$$

As stated by the general description of this technique, this is not the formal linear 7-piecewise interpolation polynomial, as the nodes do not meet the exact curve. The number of intervals and adjustments to the actual node values are significant for increasing speed on FPGA architecture, however. The slopes are all powers of 2, which, once the equation is mapped to an integer space, allows for bit-shifting. The number and spacing of the nodes were varied in order to cause this to happen. FIGS. 8A-B show graphical representations of the linear 7-piecewise approximation for hyperbolic tangent.

There are three tree-killing methods. In method 1, all the possible scores associated with each tree are scanned. If every single one of them is 0, the tree is removed. This will have no effect on the classifier accuracy (since not including the tree is the same as just adding 0 the score, which would happen anyways). This is the default method. In method 2, all possible scores are scanned. If a certain (user defined fraction) of them have a less than a certain impact (also user defined), the tree is removed. The motivation behind this is that if every bin except one has a score of 0, then the tree will be useless in almost all cases, and will be fine to eliminate. For instance, if 90% of all bins would contribute to less than 3% of the final score, then the tree would be removed. The user must be careful with this, since the user could accidentally remove too many trees, causing the classifier accuracy to suffer. In method 3, if the boost-weight falls below a certain (user-input) fraction of the average boost-weight, the tree is deemed useless and removed. For instance, if the average of 100 trees' boost-weights is 0.1, and a tree has a boostweight of 0.0001 (both reasonable possibilities), the tree is removed. It is noted that with each of these tree-removal algorithms the user has an option to re-weight the trees afterwards. If before tree-removal, the sum of the boost-weights is 5.0, then afterwards it may be 4.8. if the user opts for that, then all the values of U are recalculated for each bin in each tree with the new normalization factor. In tests, this has proved to have a minimal effect, likely because the trees being removed are largely useless.

Merging strategies may be explained with the example of 100 trees, all evaluated separately and 34 of these were removed under an algorithm. However, merging trees together mitigates the effects of tree-removal, in the same test, with trees 1-20 merged together, 21-40 merged, etc., for 5 total trees, none of the 5 were removed. At first glance, this is surprising: since the trees are ordered highest to lowest by boost-weight, tree number 5 would consist of 20 trees that were all killed in the case with all 100 trees separate. This is due to the fact that the boost-weight of a merged tree is the sum of the boost-weights of the individual trees (see EQ. 34 above). Thus, 20 trees that may each have independently had very little effect, are strong enough when combined to have a reasonable impact. This leads to another interesting effect. Even without tree-killing, when using a low-precision, more merging corresponds to better classifier performance as measured by ROC (receiver operating characteristic) curves.

The embodiments in accordance with the present disclosure include steps such as bit integer conversion, and binary gridification to cut down on this. But this case of 100 trees above, it would be advantageous to perhaps merge the 100 trees into 5 or 10 trees, rather than into one massive tree. ROC curves are a very useful guide to help pick merging patterns that optimize both classifier and firmware performance.

An interesting result that arises from tree removal is the effect of the score ranges. Using purity provides a result ranging from 0 to 1, while YesNoLeaf yields scores ranging from −1 to 1. One assumption for tree killing as outlined above is that a score of 0 indicates that the result is indeterminate, as 1 is pure signal, and −1 is pure background. However, for purity, −1 is not pure background, 0 is. Killing all the trees that returned scores of 0 would dilute the effect of trees intended to pull the scores of those bins toward being background. The true indeterminate value for purity is where S=B−>S/(S+B)=S/(S+S)=0.5. To remedy this, in tree-killing with purity-scored samples, we consider a value we've deemed the “adjusted purity”, or P′=(S−B)/(S+B). This would yield a value of 0 where S=B, 1 where the bin is pure signal, and −1 where it's pure background. Since the adjusted purity may not be returned by TMVA or Sci-kit learn, the adjusted purity can be calculated as follows:

$$\frac{S - B}{S + B} = \frac{S}{S + B} - \frac{B}{S + B} = p - \frac{B}{S + B} \qquad EQ . 23$$

Since any point that is not signal must be background,

$$\frac{B}{S + B} = 1 - \frac{S}{S + B} .$$

### Therefore,

$$P = \frac{B}{S + B} = P - ( 1 - \frac{S}{S + B} ) = P - ( 1 - P ) = 2 P - 1 \qquad EQ . 24$$

### Thus,

P′=2p−1 EQ. 2

As expected, this yields a score of 0 when S=B, 1 when B=0, and −1 when S=0. With the adjusted purity, a purity-based scoring system may be used to kill trees with bins that exclusively have scores of 0. The scores from the passing trees can then be reported as either the adjusted or un-adjusted purity based on the user's preference.

Cut removal is also utilized in the embodiments in accordance with the present disclosure. For example, in a scenario where there is a flattened three of two variables, x and y, there are xₙ cuts in the x-dimension and yₘ cuts in the y-dimension. Therefore, the flattened tree is an (n+1) by (m+1) grid. Now, there is a given cut xᵢ. On the “left” of this cut there is a column of bins with x index i in the gridspace and on the “right” of this cut there is a column of bins with x index i+1. Define Δⱼ=|score_{left}−score_{right}|. Hence, Δ=0 indicates that at that give y-position, score_{left}=score_{right}. Values of Δⱼ for each y-value of j (so the entire column) can be found. If all values of Δ at each y-position are zero, this means that every bin on the left has the same exact score as its counterpart on the right. In that case, the cut separating them is not necessary, and thus, it can be just removed, and the bins may be merged across from each other. This can be scaled up to the n-dimensional case. There will always be a “left” and “right” bin to compare across a single cut, just instead of a line separating them, it may be a plane (in the 3-d case) or hyper-plane (n-d case). When binning is used, this implementation is simple. All the cuts in each dimension may be scanned over, removing those where most or all values of A obtained from left-right comparisons are very small or zero. The exact specifications for whether or not a cut should be removed can be set by the user. This process is recursively repeated until no more cuts can be removed.

When using binary gridification, more care may be needed. Doing binary gridification essentially reforms the tree structure in each dimension, only with cuts that can be bit-shifted down quickly. Therefore, to remove cuts, it cannot be simply scanned left to right. Otherwise, a cut in the middle of the tree may be removed by accident. Thus, rather than scanning “left” to “right” looking for cuts to remove, it is scanned from the “bottom” of the tree to the “top” just like pruning on a regular decision tree. The only change is how to find which cuts to check. They are checked the same way. One question that may arise is why cuts like this exist. Why would the classifier put useless cuts like this? The answer is that the classifier does not. Instead, by merging trees, otherwise independent cuts are taken and put on the same gridspace. In this case, two cuts may end up very close to each other, resulting in one of them being “useless”.

The embodiments may also utilize pre-processing scores for triggering (e.g., via a score finder as described with reference to FIG. 10. In triggering applications, the algorithms often only care about whether an event passes or not. Machine learning algorithms often return more precise values (response values, weighted scores, purities). By rounding the bin values to ±1 in advance, a clock tick on the firmware is saved by simply returning a pass/fail value, rather than returning an unnecessarily precise value. Such pre-processing may be also useful in a variety of decision tree cases. For example, where an output score of a gradient boosted binary classification is O_{T}=tanh(Σ_{forest}αᵢ), tanh may be done for each bin in software ahead of time if all the trees can be merged, rather than reverting to piecewise approximating in firmware. Further, in the multiclassification cases, the multiclassification probabilities are defined by applying softmax to a vector of each class's summed response value. If all trees can be merged together, then the softmax may be performed on the software in advance, precomputing each class's probability within each bin.

With the novel concepts as described above, Table 1 shows improved performance and success using the embodiments in accordance with the present disclosure. Performance may be defined as the success of the classifier and the firmware. The classifier performance can be Receiver Operating Curves (ROC Curves), which plot signal efficiency vs. background rejection. By comparing the ROC curves output by the FPGA evaluation to the standard software evaluation, minimal performance loss with the firmware implementation can be confirmed. Additionally, success may be measured via the firmware statistics, such as those outlined in Table 1. In Table 1 the test case is separating electron from photon signals in a simulated dataset of a calorimeter such as those at the Large Hadron Collider. With 100 decision trees each with a maximum depth of 4 given a set of 8-bit inputs, we achieve an event evaluation latency of three clock ticks, which is less than 10 ns in our setup, with minimal resource usage.

TABLE 1
FPGA performance and hardware specification
for the benchmark problem

| Parameter | Value | |
|---|---|---|
| Hardware performance | | |
| Latency | 3 ticks (9.375 ns) | |
| Interval | 1 tick (3.125 ns) | |
| LUT | 1903 (0.16% of total) | |
| FF | 138 (0.01% of total) | |
| BRAM | 8 (0.19% of total) | |
| URAM | 0 | |
| DSP | 0 | |
| Hardware assumptions | | |
| Chip | xcvn9p-flga2104-2L-e | |
| Clock | 320 | MHz |
| Vivado version | 2019.2.1 | |
| Synthesis type | C synthesis | |
| HLS or RTL | HLS | |
| HLS interface pragma | none | |
| Software Setup | | |
| Tree depth | 4 | |
| Number of event types | 2 | |
| Input variable precision | 8 | bits |

| | |
|---|---|
| Number of input variables | 4 |
| Number of trees after merging | 10 |
| Number of tree after killing, method | 10 |
| Localizing approach, parameters | Binary gridification |
| BDT method, options | Adaptive boost, YesNoLeaf |

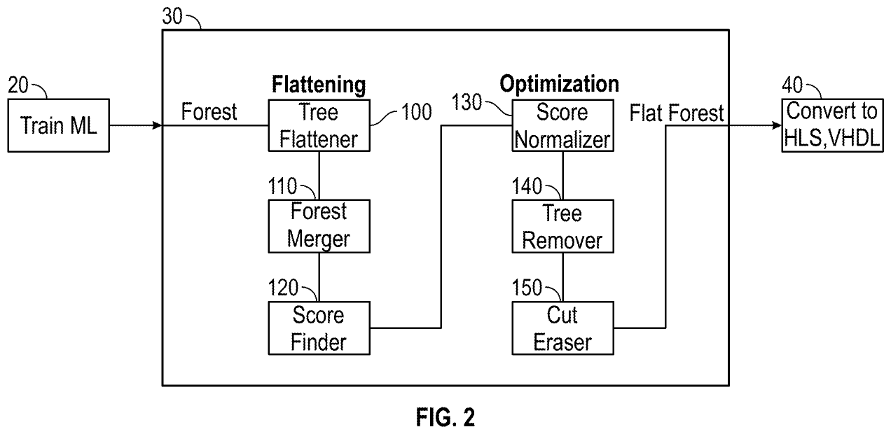

Referring back to FIG. 1, the device 10 is configured to be implemented in the electronic device 70, e.g., FPGA, for optimizing the nanosecond execution of machine learning algorithm. The device 10 may include a machine learning (ML) training component 20, a nanosecond optimizer 30 configured to optimize the trained input data, and a converter 40. The ML training component 20 is configured to receive input data 22 for determining an event score associated with the input data (e.g., machine learning data) and train 20 the input data using the machine learning algorithm and evaluates the input data 22 using an ML trainer 24, e.g., scikit-learn or TMVA. (Toolkit for Multivariate Data Analysis). In some cases, the device 10 may include tools to simplify the ML training process for, e.g., beginners. A resulting BDT (i.e., trained ML configuration) is then passed from the ML training component 20 to a nanosecond optimization framework 30 structured to optimize the BDT for implementation on, e.g., FPGAs. The nanosecond optimizer 30 may include at least one of a tree flattener configured to flatten a plurality of vertical layers of a decision three into one layer, a tree merger configured to merge a plurality of flattened decision trees into one tree, a score normalizer configured to normalize an event score of a bin of a flattened tree, a tree remover configured to remove one or more flattened trees in accordance with a user specification, or a cut eraser configured to erase a cut between bins in a flattened decision tree in accordance with the user specification. The user specification may be an instruction from the user to, e.g., erase a cut between two adjoining bins if the difference between a bin score is, e.g., less than 0.05 (as shown in FIG. 11) or any other number specified by the user. The converter 40 may be coupled to the device 10 and configured to receive the optimized BDT from the nanosecond optimizer and convert them to high-level-synthesis language for use in the electronic device 70. A detailed description of the nanosecond optimizer 30 is provided in FIG. 2.

Via the nanosecond optimizer 30, the BDT may have an increased level of performance and reduced latency using an ROC (receiver-of-characteristics) curve, lookup table (LUT), flip-flops (FF) 32, etc. The ROC curve is used to compare algorithm performance. For a binary classification problem of “signal” vs. “background,” the ROC curve plots the selection efficiency for a signal sample against that of a background sample. The selection efficiency for the background sample may be referred to as a background rejection factor because a typical problem at the LHC (Large Hadron Collider) faces a background sample that are many-orders-of-magnitude larger than the signal sample. For example, a trigger algorithm may be chosen after considering what algorithm that maximizes the selection efficiency for the signal sample for a desired rejection factor. As such, based on the ROC curve, the best trigger algorithm may be chosen. Using LUT in place of DSP, where appropriate, to execute the multiplication operation by the firmware or hardware. A neural network generally needs multiplication, which is generally resource intensive. An LUT includes a large amount of data that have already been pre-multiplied and predefined the bins based on the pre-multiplication for any input space. As such, an LUT simply takes an input data and finds the scores regarding the input immediately based on the pre-multiplied and predefined bins. As such, the LUT in accordance with the present disclosure reduces latency associated with multiplication that conventional computer devices need to perform. The optimized BDT may then be inputted 34 by a user to the converter 40. The converter 40 is structured to produce code for flexible firmware implementation, and passes the algorithm configuration (including VHDL code) to a high-level synthesis (HLS) tool 50, e.g., Xilinx™, to and synthesize firmware that can be run in, e.g., FPGAs. The device 10 may be a software package (e.g., fwXmachina) structured to provide a library of tools focusing on binary classification, simplifications for BDT evaluation on FPGAs and machine learning (ML) evaluation on FPGAs in general, beyond the scope of BDTs.

FIG. 2 is a block diagram of a nanosecond optimization framework 30 according to one particular, non-limiting exemplary embodiment of the disclosed concept. Upon receiving trained ML configuration from the ML training component 20, the nanosecond optimization framework 30 performs optimizations to the trained ML configuration. The nanosecond optimization framework 30 may include a tree flattener 100, a forest merger 110, a score finder 120, a score normalizer 130, a tree remover 140, and a cut eraser 150. The tree flattener 100 flattens trees, discussed in detail with reference to FIG. 4. The forest merger 110 is structured to merge the trees. The score finder 120 is structured to find the event score of a tree's bins. The score normalizer 130 is structured to normalize event scores of a tree's bin. By weighting the scores of a tree's bin to a boost-weight divided by the sum of the boost-weights, the score normalizer 130 eliminates the need for firmware-side multiplication in calculating the weighted average of an event. The tree remover 140 is structured to remove trees that have no impact on the scores of the trees' bins. The cut eraser 150 is structured to remove a cut that has no effect. For example, for each cut, a left-right comparison across the cut may be made for each bordering bin, and if the comparison shows very little or no effect of the cut, the cut eraser 150 removes the cut further, the cut locations even in conversion to bit integers and each variable is binned independently in parallel to find a correct score.

FIG. 3 shows a conventional decision tree 300. A decision tree is used to support decision making, and uses a tree-like model of decisions and their consequences, including chance event outcomes, resources costs, utility, etc. It provides a useful mechanism to display an algorithm including only conditional control statements. In FIG. 3, the decision tree 300 passes an event's parameters through a series of nodes 310A-D, making a ‘cut’ on a single variable at each, and using the parameters and cuts to classify the event. Through a process known as boosting, multiple trees may be used to evaluate an event where each tree has a boost-weight, and the weighted average of all the trees' outcomes define the event's final score.

FIGS. 4A-B show a bin engine using bit-shifting according to one particular, non-limiting exemplary embodiment of the disclosed concept. FIG. 4A shows a gate-level diagram 400A of the bin engine using bit-shifting for one input variable x. The dataflow is left-to-right. The input to the engine 400A is x, an N-bit value. The x is binned in L recursive binary layers via bit-shift, comparator 410 and AND gates 415 of, e.g., the FPGA. The comparator constants that correspond to each layer (l=1, 2, . . . , L) are denoted as a α, β, . . . , δ, respectively. The LUT/BRAM 420 is not being accessed for bit-shifting. There are B-1 copies of the AND gates structure corresponding to the B number of bins after Bin Eraser. The output of the AND gates 415 is entered into the IC 425 of, e.g., the FPGA. Since only one AND gate (e.g., at position b) uniquely returns in_{b}=1 while all others return 0, the list of in is converted in an LUT via an active array to out =b. The IC 425 then outputs a bin index b for the input x. Here, the output bin index b=2. AND_{B-2} and in_{B-2} are highlighted to show the activated path that leads to output b=2. FIG. 4B shows a numerical example 400B with corresponding values. The dataflow for x =13, where the engine parameters are N=4 and L=3 with three layers α, β, and δ. The bin eraser eliminates many of the possible bins to arrive at B=4 for bins b=0, 1, 2, 3. The erased bins are denoted by the dotted lines in the numerical example 400B and correspond to the dotted lines in the gate-level diagram 400A.

FIG. 5 is a schematic diagram of a bin engine using addresses 500 according to one particular, non-limiting exemplary embodiment of the disclosed concept. The bin engine 500 is coupled to the LUT 520 or block RAM (BRAM) for determination of the output based on the premultiplied, predefined bin values in the LUT 520. The input x becomes processed via the comparators 505, XORs 510, NAND gate 515, and IC 525 of, e.g., the FPGA. The comparator input values α, β, . . . δ are received from LUT 520 where each α, β, . . . δ are addressed. The input x and comparators input values α, β, . . . δ are compared and the output of the comparators 505 are XORed (except for in₀) 510. Then, the output from the XORs 510 is input to NAND gate 515, whose output is input to a processor 525 that returns output b based on the input from the NAND gate 515. Because of the direct access to he MT 520, this bin engine using addresses 500 reduces latency.

FIGS. 6A-B show tree flattening according to one particular, non-limiting exemplary embodiment of the disclosed concept. The tree flattening may be performed by a tree flattener 100 of the nanosecond optimization framework 30 as described with reference to FIG. 2. FIG. 6A shows a node tree structure 600 and a graphical representation of a conventional tree structure. The node tree structure 600 shows passing of event parameters through nodes 610A-C at different depths, e.g., depths i & ii. The node tree structure 600 shows one tree structure with two variables, xₐ, x_{b}, and one cut threshold for each variable (cᵢ, cᵢᵢ). The node tree structure 400 indicates a decision making processes, where the final terminating leaves, O₀₀ and O₀₁, include an output score s (not shown) with subscripts. The node structure is an iterative procedure according to a number of depths of a tree. A graphical representation 605 of the conventional tree on the two-dimensional plane, where xₐ runs on the x-axis and x_{b} runs on the y-axis, shows a range defined by each cut threshold. The graphical representation 605 shows that binning of the conventional tree structure is sequential. FIG. 6B shows a node structure 620 of the conventional tree that has been flattened to one depth structure by inserting “ghost” dotted lines 640. The graphical representation 625 of the flattened tree shows the “ghost” dotted line 640, corresponding to the O₁₀ vs. O₁₁ leaves in the node structure of the flattened tree 620. The graphical representation 625 of the flattened tree illustrates that binning in each variable is independent of other variables.

FIG. 7 illustrates forest merging according to one particular, non-limiting exemplary embodiment of the disclosed concept. Forest merging may be performed by the forest merger 110 as described with reference to FIG. 2. FIG. 7 shows visual binning examples for two variables, xₐ, x_{b}, demonstrating a merger of two flattened tree structures T_{α}, T_{β} into one tree T_{αβ}. The flattened tree T_{α} has a boost weight W_{β} and its graphical representation 625A in the two-dimensional plane shows binning in each variable is independent of other variables. The flattened tree has a boost weight w_{β} and its graphical representation 625B in the two-dimensional plane shows binning in each variable is independent of other variables. In each region defined by a cut threshold c, the output scores are printed as, e.g., O_{α00} (corresponding to flattened tree T_{α} and bin 00). The vertical and horizontal lines of flattened trees T_{α} and T_{β} are superimposed onto a graphical representation 625C of the merged tree T_{αβ} in one two-dimensional plane. The output score in each region of the merged tree averages the corresponding scores of the flattened trees T_{α}, T_{β}.

FIG. 8 illustrates binary binning strategy 800 according to one particular, non-limiting exemplary embodiment of the disclosed concept. FIG. 8 shows a visual example for one variable xₐ to demonstrate the choice of bin boundaries and bin layers. In this example, the result of the training step are three bins in the conventional bin boundaries. If the bin boundaries occur in multiples of a power of two, then bit shifting can be employed to reduce the latency to find the bin index of an event. In this example, 2²=4 is chosen as the fixed bin width and six primed bins are arrived. However, the binary gridfication approach potentially incurs a large resource usage in cases where a large amount of variations occurs in a small area. In that case, a “recursive” approach may be employed. The implementation may not be recursive since it can be done by combinatoric logic.

FIG. 9 illustrates staircase method for angled cut approximation 900 according to one particular, non-limiting exemplary embodiment of the disclosed concept. The staircase method in FIG. 9 uses a possible linear Fisher discrimination in two dimensions. Boosted decision trees and cut-based classifiers rely on straight, one dimensional cuts. However, others such as Fisher Linear Discriminant and neural networks rely on linear cuts in multiple dimensions. A Fisher discriminant draws a single cut of the form c₁x₁+c₂x₂ +. . . +d=0 for variables x₁, x₂. Therefore, in the easily-visualized two-dimensional case, the variable space is partitioned by line of the form c₁x +c₂y+. . . +d=0, In the three-dimensional case, the variable space is partitioned by a plane, and so forth. FIG. 9 demonstrates a sample two-dimensional case, S showing a region where most of the signal data-points S′ are included, B showing a region where most of the background data-points B′ are included and U showing an unknown region. The S′ and B′ data-points are separated by the cut shown. This evaluation in firmware is computationally expensive. Therefore, to simplify it, a rotation may be applied on the FPGA to simplify the problem or Fisher discriminant may be approximated as a grid-space beforehand in software as done with decision trees. First, evenly spaced points are placed along the line, such as the white dots in FIG. 9. A line is drawn in every dimension through each point, constructing the n-dimensional grid-space. All bins that fall fully on one side of the partition are assigned that value (either 1 or −1 for signal and background in this example). This leaves some bins straddling the cut. These are marked as indeterminate, or a score of 0 in such case.

FIGS. 10A and 10B illustrate piecewise approximation of hyperbolic tangent (tanh) according to one particular, non-limiting exemplary embodiment of the disclosed concept. FIG. 10A shows a graph 1000A showing approximation of smooth curve to a straight line. Since most nonlinear functions are either costly or impossible to implement with exact arithmetic on firmware, piecewise approximation achieves a very fast calculation within an acceptable error, thereby reducing latency and increasing efficiency. For example, hyperbolic tangent is a nonlinear function that is bounded in the range [−1, 1], requiring much time and area to instantiate on FPGA architecture. As such, FIG. 10A shows linear 7-piecewise approximation for tanh as described with reference to FIG. 1. FIG. 10B shows a graph 1000B showing the percentage error with the piecewise approximation of tanh. The graph 800B indicates the linear 7-piecewise approximate for tanh yields the percentage errors within the error rate (e.g., ±5%).

FIG. 11 illustrates cut-removing 1100 according to one particular, non-limiting exemplary embodiment of the disclosed concept. The cut-removing 900 may be performed by a cut eraser 160 as discussed with reference to FIG. 2. In FIG. 11, a two-dimensional example 1100A shows that only one cut A is eligible to be removed. There is a left column 1120L and a right column 1120R with respect to cut A. The differences Δ between the scores of the left column 1120L and the right column 1120R on a given y-axis are either zero or near zero (0.05). Whereas cuts B and C have Δ that is much greater than zero (e.g., |−0.6-0.7|), Thus, cut A can be removed to reduce latency and increase efficiency. A two-dimensional example 1100B shows that the cut A has been removed.

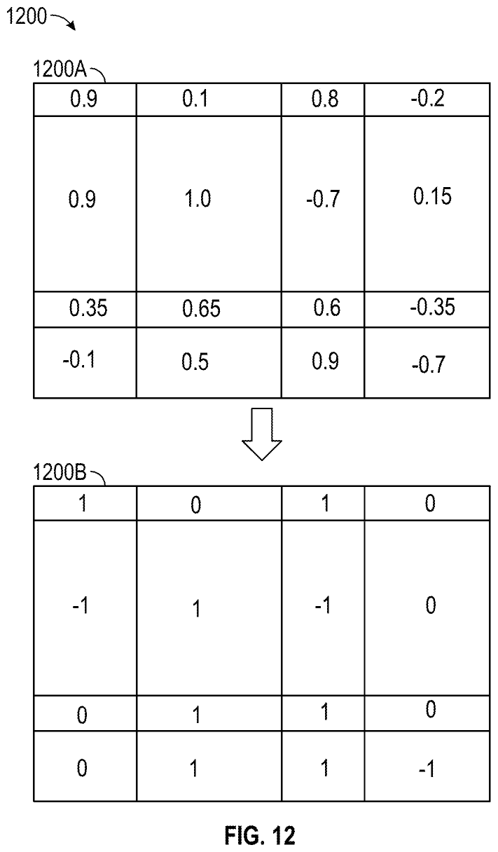

FIG. 12 illustrates a score finder 1200 according to one particular, non-limiting exemplary embodiment of the disclosed concept. The two-dimensional example of pre-evaluating scores for triggering in FIG. 12 demonstrates that for a two-dimensional gridspace where any value over 0.5 in 1200A gets rounded up to 1 in 1200B, and value below −0.5 in 1200A gets rounded down to −1 in 1200B, and anything else in 1200A is rounded to 0 in 1200B. Such rounding is what the FPGA would see. In some cases, there may be another FPGA dedicated to further examine the unknown situations (i.e., the score is zero), thereby creating a multi-layer, multi-level decision procedures using the binning strategies and optimization processes described herein. It is noted that such rounding may be done only when all trees are merged together since each tree has a different grid.

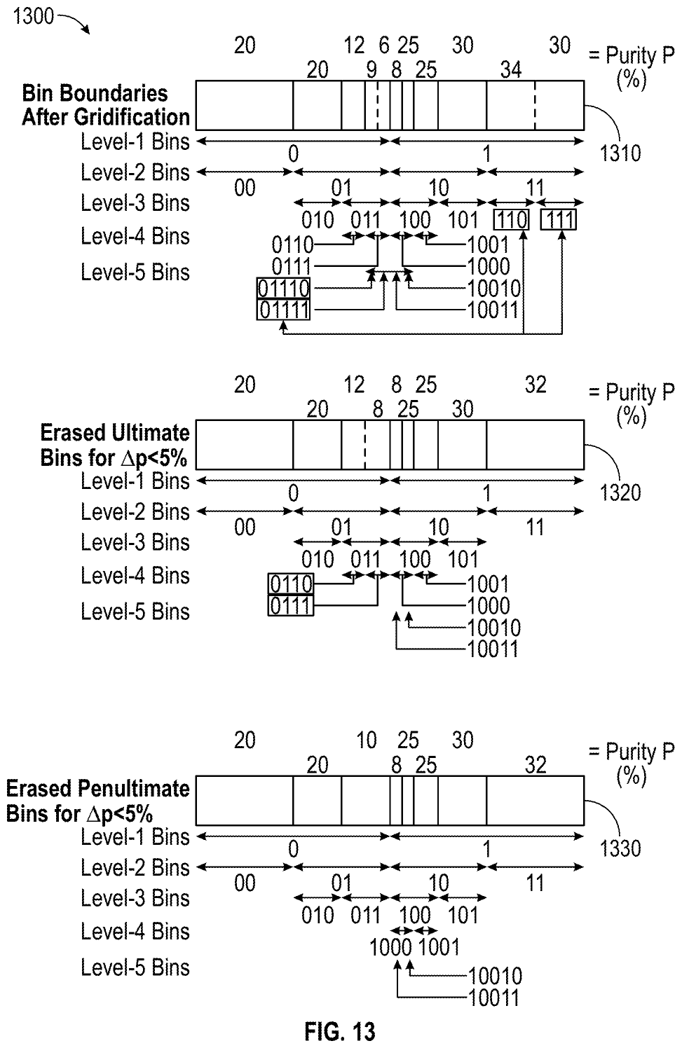

FIG. 13 illustrates bin erasing 1300 according to one particular, non-limiting exemplary embodiment of the disclosed concept. The bin erasing 1300 may be performed by a bin eraser, which may be a part of the device 10 as described with reference to FIG. 1. The visual example in one variable is xₐ demonstrates the elimination of bin boundaries in different bin layers, e.g., level 1-5). FIG. 13 shows bin boundaries 1310 after binary gridification. Then, ultimate bin numbers 110, 1111, 01110, and 011111 are removed based on purity (%). Then, new bin boundaries 1320 are formed after removing the bin numbers 110, 1111, 01110, and 011111. Next, penultimate bin numbers 0110 and 0111 are removed for change in purity less than five leaving new bin boundaries at 1330. Thus, the bin eraser eliminates bins until a desired maximum bin numbers is reached (e.g., erasing bins to arrive B=4 for bins b=0, 1,2,3 in the example used in FIGS. 4A-B.

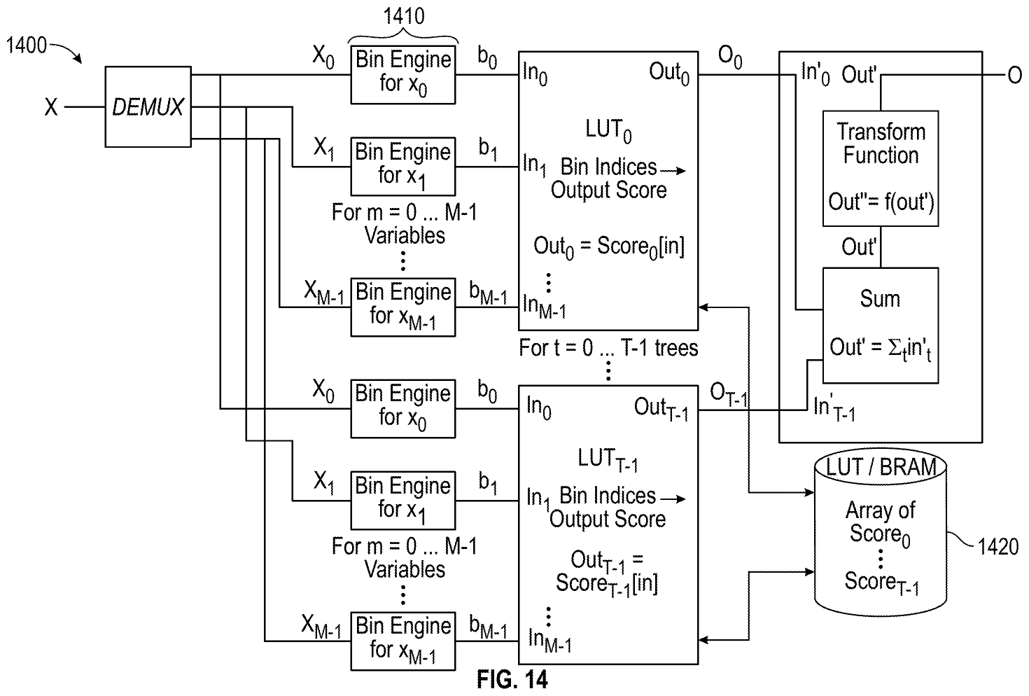

FIG. 14 is a schematic block diagram of an evaluation processor 1400 according to one particular, non-limiting exemplary embodiment of the disclosed concept. The evaluation processor 1400 illustrates the electronic design corresponding to a flattened BDT forest evaluation. For each tree, an input event is binned in each variable by the Bin Engines (bin engines elaborated on in FIGS. 4A and 5) 1410. These bins 1410 are used to find the corresponding normalized score from a LUT 1420 specific to that tree. The score O₀-O_{T-1} from each tree is summed to provide a weighed event-score O.

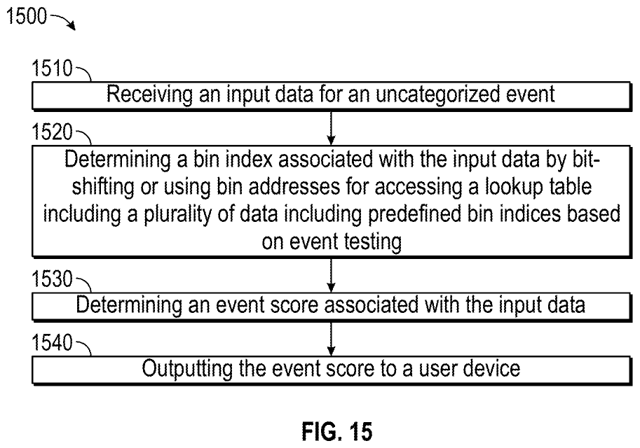

FIG. 15 is a flowchart for a method 1500 of determining events scores using a device configured to be implemented in an electronic device for nanosecond execution of machine learning algorithm according to one particular, non-limiting exemplary embodiment of the disclosed concept. The method 1500 may be performed by the electronic device, e.g., a field programmable gate array, an application specific integrated circuit, etc., or any component thereof including the device implemented and components of the device implemented. The device configured to be implemented in the electronic device may be the device as described with reference to FIG. 1.

At 1510, the electronic device receives an input data for an uncategorized event.

At 1520, the electronic device determines a bin index associated with the input data by bit-shifting or using bin addresses for accessing a lookup table comprising a plurality of data including predefined bin indices based on event testing. In some example, a firmware of the device implemented in the electronic device may determine the bin index.

At 1530, the electronic device determines an event score associated with the input data.

At 1540, the electronic device outputs the event score to a user device. The user device may be any device (e.g., a vehicle, a robot, a cellular phone, a tablet, a storage coupled to the electronic device, etc.) electrically or communicatively coupled to the electronic device to receive the event scores from the electronic device.

FIG. 16 is an autoencoder system 2000 for nanosecond anomaly detection or encoded data transmission according to one particular, non-limiting exemplary embodiment of the disclosed concept. The autoencoder system 2000 includes a device 2010 configured to implement and optimize machine learning algorithm execution, a firmware 2060 coupled to the device 2010, and an electronic device 2070 configured to implement the firmware 2060, The device 2010 may be a software (e.g., fwXae) and include a deep decision tree (DDT) autoencoder 2100, and an HLS converter 2040. The DDT autoencoder 2100 is configured to receive and encode input data (x) 2101 and simultaneously decode the encoded data w via a decision tree grid using deep decision trees, when used for nanosecond anomaly detection. The DDT autoencoder 2100 is configured to transmit the encoded data by splitting bin engines into an encoding part and a decoding part and explicitly introduce the encoded data that are transmitted over a large physical distance (e.g., without limitation, greater than 0.1 in the ratio of the anomaly score of the input data with respect to the peak location of the training sample) by a method of signal transmission, when used for nanosecond encoded data transmission.

In general, an autoencoder encodes the input data x into a lower-dimensional latent representation w and decodes w to reconstruct the original data as \hat{x}. The autoencoder has an output that is the same dimension as the input, i.e., h(x)=\hat{x}. Typically, the latent space is lower dimensional than the input space, i.e., k<1, but this is not necessarily the case in technical considerations. The quality of the autoencoder is determined by distance (also known as error) of reconstructed data \hat{x} with respect to the original input x. The distance Δ between the input and output typically uses the 2-norm metric, d₂(x, \hat{x})=Σᵢ(xᵢ−\hat{x}ᵢ)². However, the 1-norm metric, d₁(x, \hat{x})=Σᵢ|xᵢ−\hat{x}ᵢ|, is better suited for firmware implementation due to its simplicity. Tables 2 shows distance metrics.

TABLE 2
Distance metrics to compute the input data
x and the reconstructed data \tilde{x}

| Name | Distance | Comments |
|---|---|---|
| 1-norm | d₁(x, x\hat{ }) = Σᵢ \|δᵢ\| | Default, fast |
| 2-norm | d₂(x, x\hat{ }) = Σᵢ \|δᵢ\|² | Traditional, slow |
| Max | dₘₐₓ = max(\|δ₀\|, . . . ) | Must compare a lot |
| Min | dₘᵢₙ = min(\|δ₀\|, . . . ) | Must compare a lot |

For Table 2, δᵢ≡xᵢ−\hat{x}ᵢ.

While a conventional autoencoder uses real-valued variables, the autoencoder 2100 may use N-bit integers for the input data x and the reconstructed data \hat{x} and M-bit integers for the latent variables. Thus, for the range 0 to n=2^{N}−1, Zn may include underflows mapped to 0 and overflows mapped to n-1. The latent variables may range from 0 to m =2NN −1 with no underflow and overflow. The latent variables represent the indices of the terminal leaf in the decision tree. The input data x is a vector of length l, the latent data w is a vector of length k, and the reconstructed data \hat{x} is a vector of length I. The encoding function is:

f: Zₙ^{l}→Zₘ^{k} EQ. 26

The decoding function is:

g: Zₘ^{k}→Zₙ^{l} EQ. 27

The autoencoder function is:

h=f∘g EQ. 28

where h: Zₙ^{l}→Zₙ^{l}. The distance between input and output is d(x, h(x)).

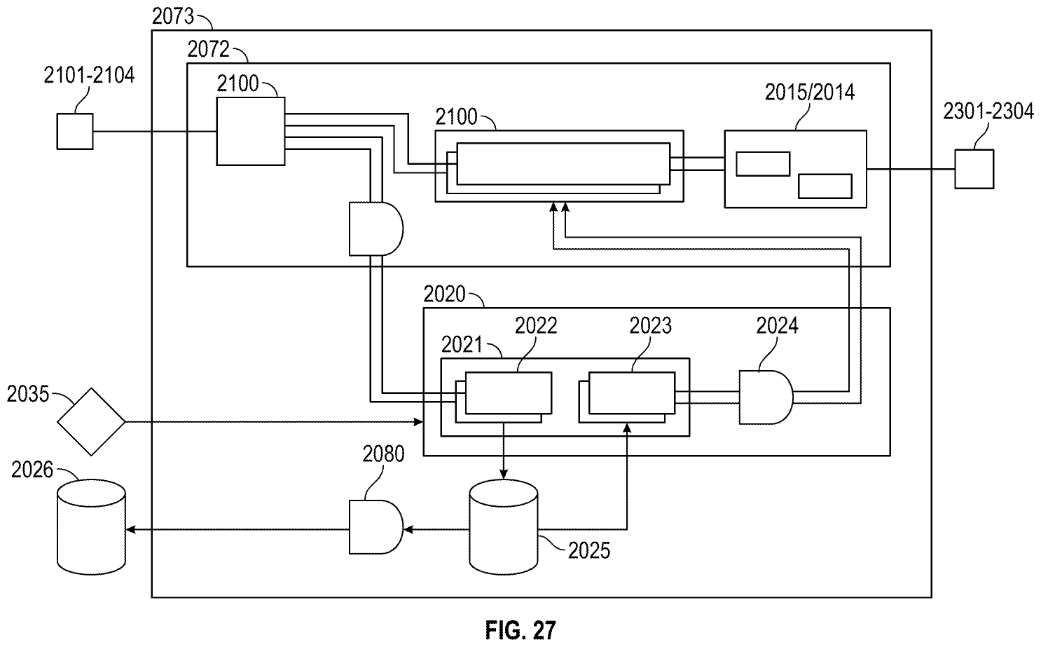

Referring back to FIG. 16, the DDT autoencoder 2100 includes (i) a machine learning (ML) trainer configured to determine parameters for the autoencoder and cut thresholds for DTG using importance trainer, (ii) a nanosecond optimizer 2030 including a decision path (DP) architecture configured to logically flatten a plurality of combinations of comparisons that connect initial node to terminal nodes of a decision tree into one set of decision paths for simultaneous evaluation, (iii) a converter 2040 coupled to the autoencoder 2100 and configured to receive the and convert the DTG to a language for high-level-synthesis to produce hardware description language; and a table of characteristics 32,2032 coupled to the autoencoder 2100 and configured to store cut thresholds corresponding to the one set. The autoencoder 2100 may be self-trained periodically according to user specifications by the importance trainer using one-sample training data in an unsupervised manner by using the input data 2101 simultaneously stored in a memory. The unsupervised ML of the DDT autoencoder 2100 is discussed in detail with reference to FIG. 27.

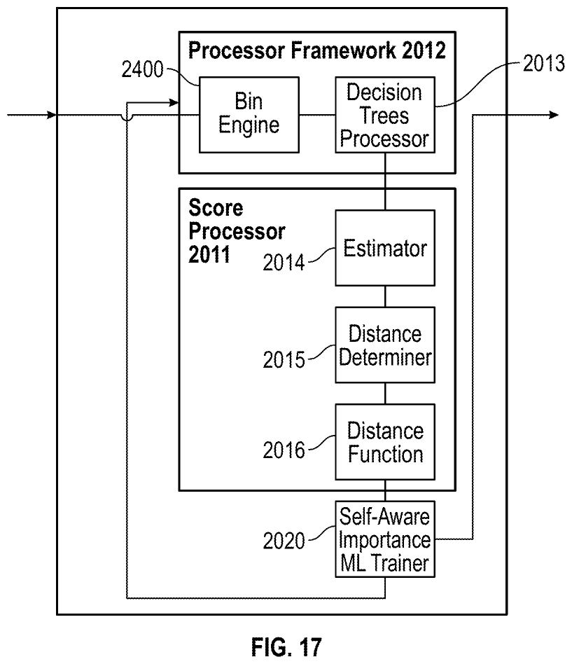

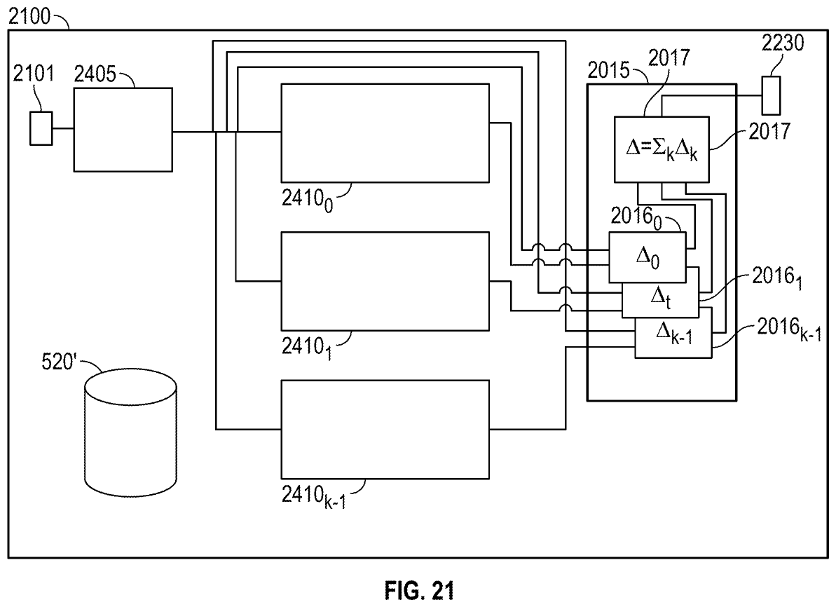

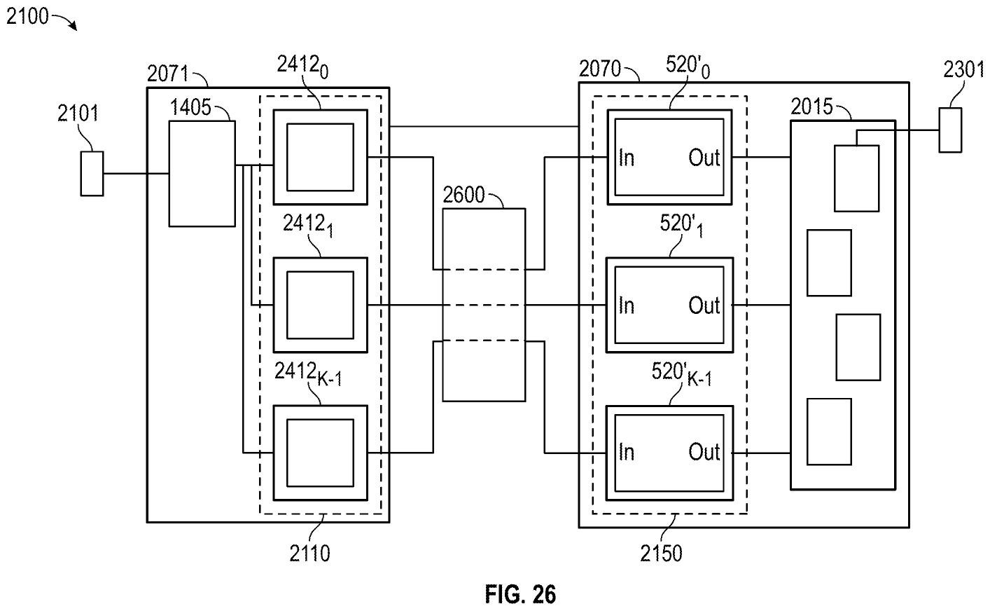

The firmware 2060 is coupled to the converter 2040 and the lookup table 520, 520′ (as shown in FIGS. 5 and 21-23), The firmware 2060 is configured to receive the hardware description language. The firmware 2060 includes (i) a plurality of deep decision tree engines (e.g., DDT engines 1410 as shown in FIG. 21) configured to receive copies of the input data and evaluate each decision path independently from a plurality of structure of the decision tree, and (ii) a processing device configured to process output from the plurality of deep decision tree engines 2410 and including an estimator (e.g., the estimator 2014 of FIG. 17) configured to reconstruct the input data using the encoded data and a distance determiner (e.g., the distance determiner 2015 of FIG. 17) configured to determine a distance between the input data 2101 and the reconstructed data (\hat{x}), where the distance is indicative of detected anomaly based on a determination that the distance is higher than a distance of reconstructed non-anomaly background event. The distance indicates a deviation from the non-anomaly background event. Where the distance is within a threshold distance (e.g., without limitation, less than or equal to 0.1 in the ratio of the anomaly score of the input data with respect to the peak location of the training sample) according to user specifications, the distance is indicative of faithful reconstruction. In such case of the faithful reconstruction, the autoencoder 2100 transmits the encoded data within tens of nanoseconds, thereby achieving faster, efficient data transmission than the data transmission by the conventional autoencoders using neural network. The autoencoder 2100 performing nanosecond encoded data transmission is discussed further in detail with respect to FIG. 26. The firmware 2060 may be implemented in the electronic device 2070. The electronic device 2070 may be a field programmable gate array, an electronic switch, an application-specific integrated circuit (ASIC)).

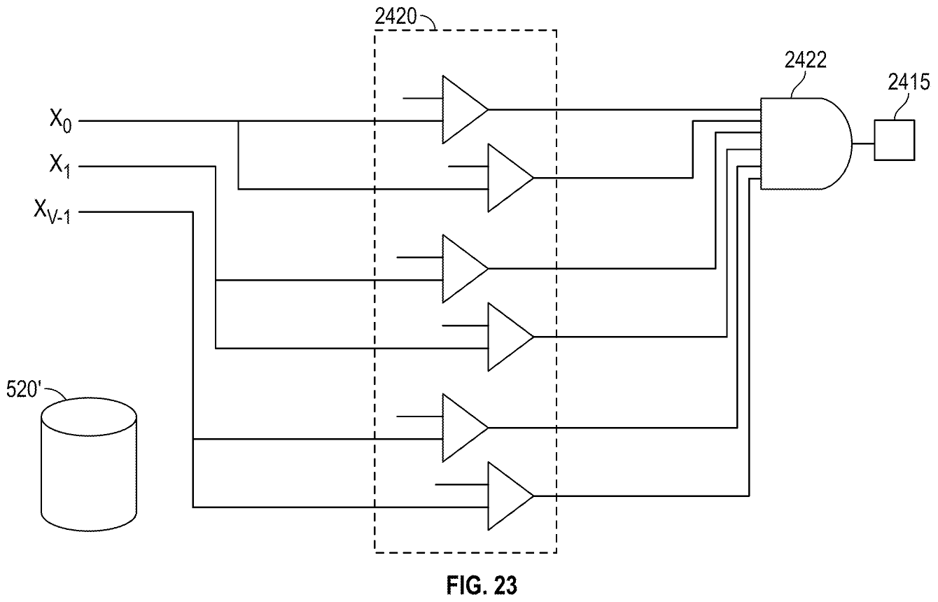

The DTG acts as encoder and decoder and performs encoding and decoding simultaneously. The DTG utilizes a deep decision tree engine (e.g., 2410₀, 2410₁, 2410_{K-1} of FIG. 21) based on the simultaneous evaluation of the set of decision paths, each decision path localizing the input data 2101 according to upper and lower bounds on each input variables as shown in FIG. 23. While a deep decision tree is a logically flattened tree, the DDT architecture is different from the decision tree architecture of the nanosecond optimizer 30, which flattens each tree so that binning in each variable is performed simultaneously. This simultaneous binning, however, may present difficulties when maximum depth D is much greater than 4 (i.e., D >>4) because the complexity grows as 2D. For anomaly detection, deep decision trees (e.g., the decision trees with maximum depth D=0 (10)) may be better suited. DDT is a set of B decision paths for decision tree with B terminal nodes, i.e., {P₀, P_{B-1}}. Each bin b∈B at depth d is connected to a starting node in a unique combination of at most d comparisons. The set of comparisons defines the decision path P_{B}. The simultaneous (parallel) evaluation of the decision paths yields a one-hot vector that indicates the bin location of the input data 2101.

By utilizing decision trees, the autoencoder system 2000 eliminates the need for costly operations, such as multiplication, matrix manipulations, and evaluation of activation functions, that may increase algorithm latency and/or FPGA resource utilization, As such, the autoencoder system 2000 in accordance with the present disclosure achieves extremely fast (e.g., less than tens of nanoseconds) anomaly detection and/or data transmission. Further, the modified lookup bin engines 2400 allow simultaneous encoding and decoding of data. This also improves latency since the autoencoder bypasses the need to produce latent space data. In addition, the use of deep decision tree architecture further improves the latency and efficiency in anomaly detection and/or data transmission. For example, the benefit of the DDT as opposed to flattened decision tree of maximum depth D may be seen by comparing the number of logic operations that define the decision trees. A flattened decision tree has 2^{D} terminal nodes. Each terminal node contributes D comparisons for a total of D·2^{D} comparisons, which is the maximum possible comparisons for the DDT in extreme cases where every binary split is populated. The minimum possible comparisons may be determined, however, by considering the DDT where one of the nodes is terminated in every binary split. In this situation, the terminal nodes after the first split requires one comparison, the terminal node after the second split requires two comparisons, and so forth. The total number of comparison operations then becomes ½D(D+1)˜D². For example, if the maximum depth D=15, the minimum and maximum number of operations become 120,000 and 500,000, respectively. As such, the DDT autoencoder 2100 may determine the distance between the input data x and the reconstructed data \hat{x} by performing only a fraction of the number of logic operations required by the flattened decision tree of maximum depth D.

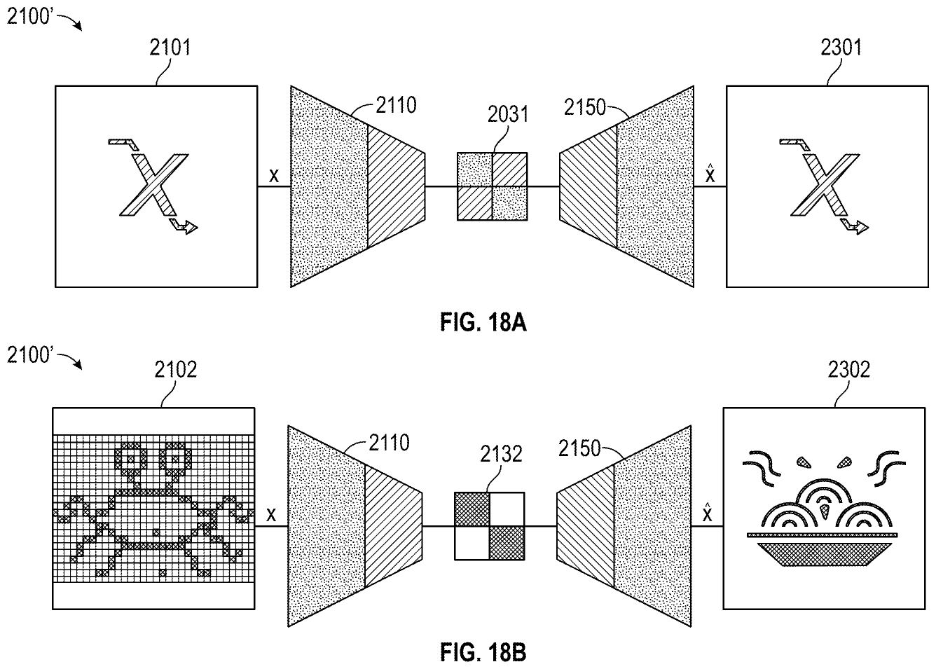

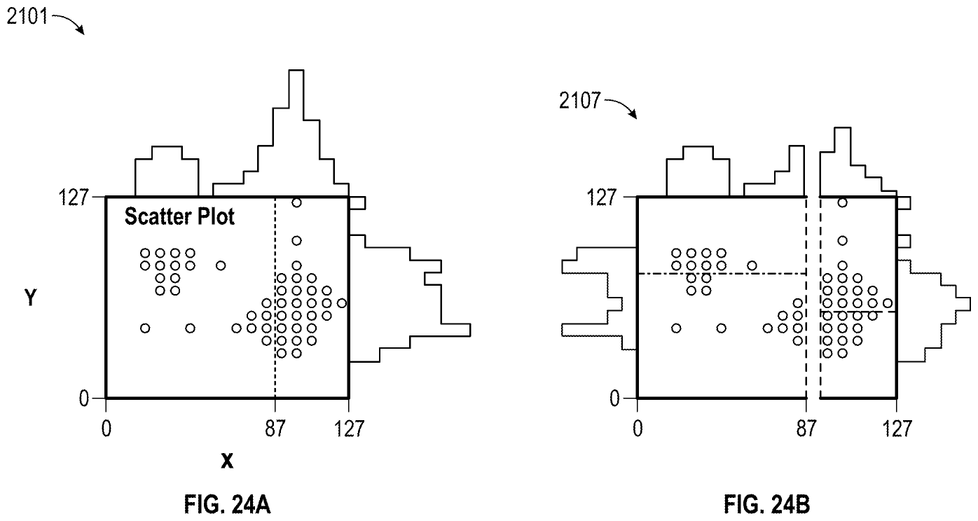

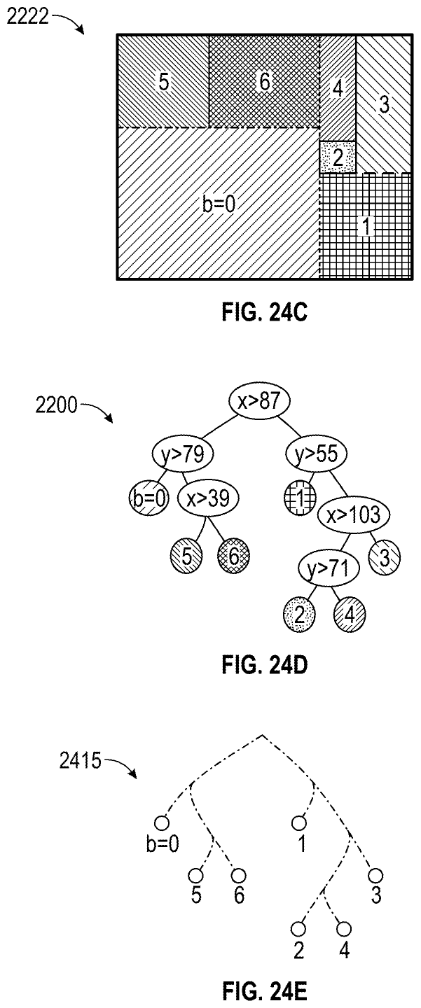

FIG. 17 is a block diagram of a framework of the autoencoder system 2000 according to one particular, non-limiting exemplary embodiment of the disclosed concept. Upon receiving the input data 2101, the autoencoder system 2000 includes a score processor 2011, processor framework 2012, and self-aware importance trainer 2020. The processor framework 2012 includes bin engines 2400 and decision trees processor 2013 including a tree flattener 100 and deep decision trees 2200. The score processor 2011 includes an estimator 2014, distance determiner 2015. and distance function 2016. The processor framework 2012. takes the inputs and either uses the flattened tree architecture of FIG. 6B or the logically flattened tree architecture using decision paths of FIG. 24C-E. The former uses bin engines 2400 whereas the latter uses decision tree processor 2013. The output of the processor framework 2012 is the input of the score processor 2011. Within the score processor 2011, the estimator 2014 gives the estimate of the input data, which is used to compute the distance by the distance determiner 2015 for each tree. Each distance is combined by the distance function 2016. The output of the score processor 2011 passes through the self-aware importance ML trainer, whereby the accumulated data may periodically update, according to user specifications, the parameters of the Processor Framework 2012. The output of 2016 is also the output of 2020. The processor framework 2012 also includes deep decision tree engine 2410 (as shown in FIG. 21) as well as lookup table 520 (as shown in FIG. 5) and bit-shifting 400A (as shown in FIG. 4A). The deep decision tree engine 2410 is configured to receive copies of the input data x and evaluate each decision path independently from a plurality of depth associated with structure of the decision tree. Decision trees processors 2013 include tree flattener 100 and deep decision trees (DDTs) 2200. Decision trees are flattened, either physically or logically, by the tree flattener 100 and the input data 2101 is encoded and decoded by the deep decision trees (DDTs) 2200. The DDT architecture is explained in detail below. The estimator 2014 is configured to estimate the input data 2101 from the decoded data (\hat{x}). The distance determiner 2015 is configured to calculate distances Δ between the input data (x) 2101 and the decoded data (\hat{x}) 2301. The distance function 2016 includes a default or other distance functions (e.g., without limitation, Manhattan distance function). The ML trainer 2020 may also train the DDT autoencoder 2100. These framework is discussed in detail regarding the DDT autoencoder 2100 with reference to FIGS. 18A-23, The autoencoder system 2000 utilizes the score processor 2011, the processor framework 2012, and the tree flattener 100 that are used by the nanosecond optimizer 30 utilizing the BDTS.

FIGS. 18A-B illustrate autoencoder concepts, including two use cases of a conventional autoencoder 2100′. The two cases include a faithful reconstruction of an input and an errant reconstruction of an input. In general, an autoencoder 2100′ inputs x, encodes it to w, and then estimates the input as \hat{x}, as follows:

$$x {\overbrace{{⟶}^{encoder} w {⟶}^{decoder}}}^{autoencoder} \hat{x} \qquad EQ . 29$$

metric d compares the input and the output to provide a distance Δ=(x, \hat{x}). A faithful estimate yields a relatively small distance (Δ°0) while an errant estimate results in a relatively large distance (Δ>>0). The threshold cutoff (e.g., without limitation, 0.1 in the ratio of the anomaly score of the input data with respect to the peak location of the training sample) of what is considered small and large are according to user specifications. That is, if the distance Δ is less than or equal to, e.g., without limitation, 0.1 in the ratio of the anomaly score of the input data x with respect to the peak location of the training sample, then the estimate is a faithful reconstruction of the input data x. If the distance Δ is greater than, e.g., without limitation, 0.1 in the ratio of the anomaly score of the input data x with respect to the peak location of the training sample, then the estimate is an errant reconstruction of the input data x. FIG. 18A illustrates an autoencoder 2100′ yielding a faithful reconstruction of the input (x) 2101 except for in rare circumstances. Input data (x) 2101 is inputted to an encoder 2110, which encodes the input data 2101, and the decoder 2150 decodes encoded data (w) 2131. As the decoded data x represents faithful reconstruction of the input x, the autoencoder 2100′ may be used for encoded data transmission. As such, the recipient of the encoded data 2130 can use the decoder 2150 to estimate the original input 2101. The autoencoder 2100′ may be trained to recognize letter-like images. FIG. 18B illustrates an autoencoder 2100′ yielding an errant reconstruction of the input (x) 2102, represented by an image of a crab. The autoencoder 2100′ inputs the image to the encoder 2110. The decoder 2150 decodes the encoded data (w) 2132. As the decoded data represents an errant estimate, the autoencoder 2100′ may be used for anomaly detection. As shown in FIGS. 18A-B, the same autoencoder 2100′ may be used for both efficient data transmission and anomaly detection purposes simultaneously.

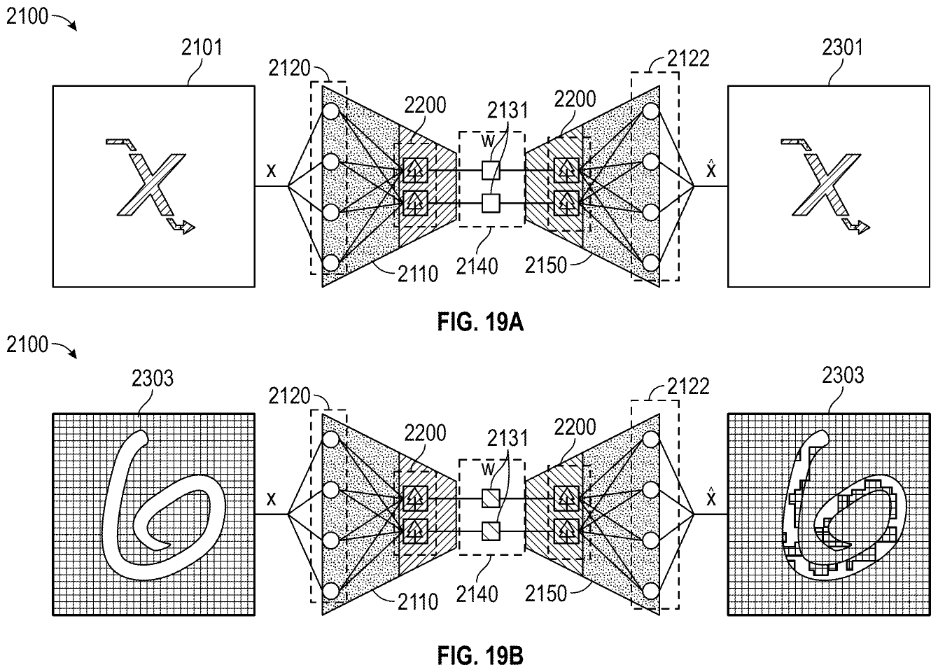

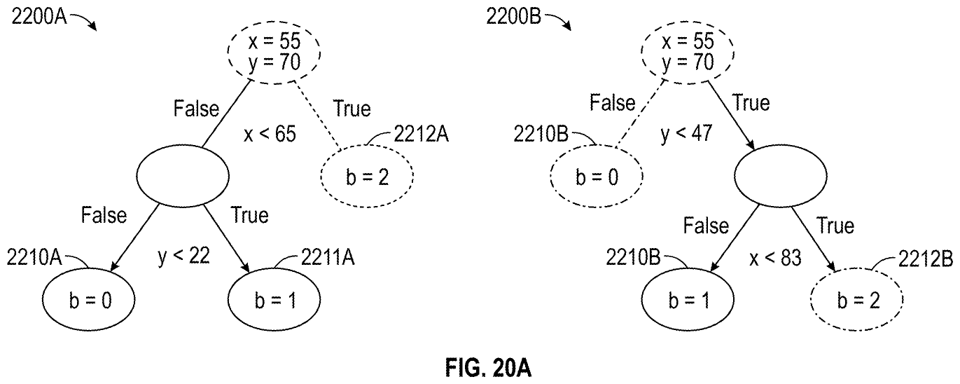

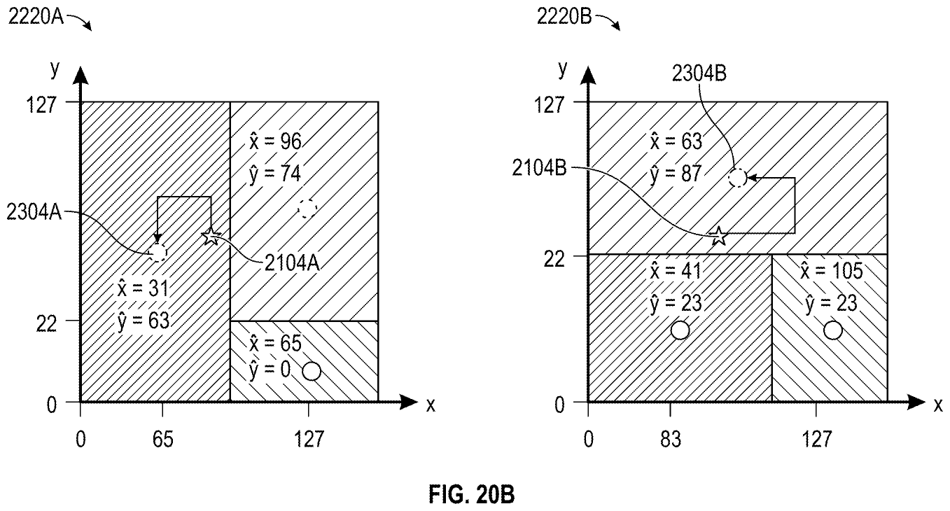

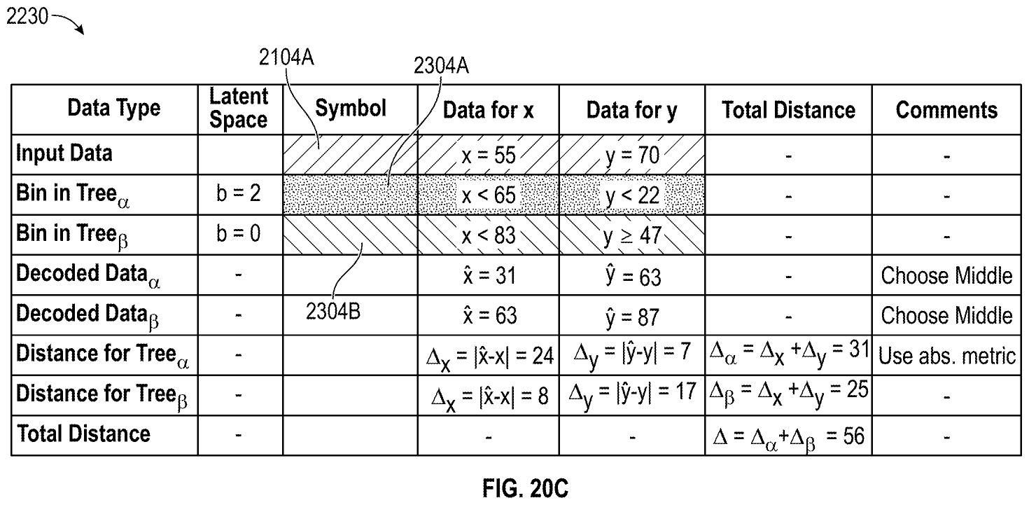

FIGS. 19A-B illustrate a deep decision tree (DDT) autoencoder 2100 for use in a field programmable gate array (FPGA) according to one particular, non-limiting exemplary embodiment of the disclosed concept The DDT autoencoder 2100 is configured to receive input data (x) 2101, encode the input data 2101 and simultaneously, decode the encoded data (w) 2131 using the same decision trees 2200. In FIG. 19A, input data (x) 2101 is input to the autoencoder 2100 and represented by four variables 2120. The input data 2101 in 4D space feeds the network that reduces the information to the encoded data (w) 2131 in a 2D latent layer 2140. The autoencoder 2100 acts both as an encoder 2110 and a decoder 2150 simultaneously. The DDT autoencoder 2100 encodes the input data 2101 using two deep decision trees 2200, converting the input data 2101 into the encoded data 2131 of the two values (w) in the latent layer 2140. Simultaneously, the decoder 2150 decodes the encoded data (w) 2131 using the same two deep decision trees 2200 and different four variables 2122, converting the two values to reconstructed version of the input data 2101. The decoded data \hat{x} 2150 is outputted. Simultaneous encoding and decoding with decision tree grid is described in detail with respect to FIGS. 20A-C. In FIG. 19B, the DDT autoencoder 2100 encodes input data (x) 2103 in the latent space 2140 and simultaneously decodes the encoded data (w) 2133. The input data (x) 2103, represented by an image of a handwritten number six in, e.g., without limitation, 28×28 pixels in 8-bit grayscale, is converted to, e.g., without limitation, 784-length input vector that is represented by the four variables 2120. The input vectors are fed into two decision trees 2200 that act as the encoder 2110. The autoencoder 2100 is trained on, e.g., without limitation, 60,000 images of handwritten zero to nine. The training may be done by random forest with, e.g., without limitation, 100 decision trees at a depth of 10. The latent space 2140 is populated by a set of bin numbers of terminal nodes. The same two decisions trees 2200 serve as the decoder 2150, but the latent space 2140 is only implied in order to achieve simultaneous encoding and decoding, i.e., x→\hat{x}.

FIGS. 20A-C illustrate simultaneous encoding and decoding using a DDT autoencoder 2100 according to one particular, non-limiting exemplary embodiment of the disclosed concept. A decision tree divides the input space R^{J} (i.e., terminal nodes) into B partitions (i.e., bins). FIG. 20A shows a set of decision trees α and β, 2200A and 2200B, respectively, which are used as an encoder and FIG. 20B shows the same decision trees (a decision tree grid (DTG) diagrams α and β, 2220A and 2220B, respectively) used as a decoder. The input data x (xy in 2D) is represented as a star 2104A,B and the decoded data (reconstruction, estimates, output) is represented as a dark circle 2304A,B. The encoding occurs when the decision tree 2200A,B processes an input vector x to place it into a one of the partitions labeled b∈Z_{B}, where Z_{B} is a bin number, Z is an integer, and B stands for a bin. The forest of T decision trees then produces the set w={b₀, b₁, . . . b_{T-1}} that is in the latent space, i.e., w∈(Z_{B})^{K}, where K=T. The two-dimensional xy input space is partitioned into three bins (2210-2A for decision tree α and 2210-2B for decision tree β) in the forest of two decision trees α and β. The encoding produces a set of bin numbers w={2,0}. The decoding occurs when w produces a set of decoded data \hat{x}, using the same forest. Each bin number b corresponds to a partition in R^{J}. This may be a hyperrectangle P_{b} defined by a set of minimum and maximum in each of the J dimensions, P_{b}={{x_{b,0}^{min}, x_{b,0}^{max}}, . . . , {x_{b,j-1}^{min}, x_{b,j-1}^{max}}}. One way to estimate x∈P_{b} is by considering the mean value of the range in each dimension, i.e., \hat{x}ₘₑₐₙ=mean(P_{b})≡{{x_{b,0}^{min}, x_{b,0}^{max}}, . . . , {x_{b,j-1}^{min}, x_{b,j-1}^{max}}}. Another estimate can be the minimum and maximum of each range, i.e., \hat{x}ₘᵢₙ=min(P_{b}) and \hat{x}ₘₐₓ=max(P_{b}), respectively. Numerous estimates may be constructed similarly, but the mean value is used here as default. In FIG. 20B, the bin numbers w={2,0} are decoded as {\hat{x}_{α}, \hat{x}_{β}}={{31,63}, {63,87}} for the two decision trees α and β. While the encoding and decoding are introduced as two separate steps with the latent space separating the encoding and decoding, they are executed simultaneously and bypasses the latent space altogether. For x that would have been placed in bin b of a decision tree, the output of the decision is the value \hat{x}ₘₑₐₙ for bin b. In FIG. 20A, the input x in 2D space (xy) is {55,70} and the output is {\hat{x}_{α}, \hat{x}_{β}}={{31,63}, {63,87}} without needing to produce or reference the latent layer. Further, a set of distances between the input and output is calculated using a metric d. The set of distances is Δ≡{Δ₀, . . . , Δⱼ₋₁}, where Δⱼ≡d (x, \hat{x}ⱼ) for j (integer) in the range. Manhattan distance d(a,b)=Σᵢ|aᵢ−bᵢ| is used as the default metric and is driven by the firmware 2060. The distances are combined by a simple sum, i.e., Δ≡ΣⱼΔⱼ. FIG. 20C shows a table 2230 including a set of distances Δ. In FIG. 20C, the distances for the two decision trees α and β are {Δ₀, Δ₁}={31, 25}, resulting in the combined distance Δ=31+25=56. Distance estimation is discussed further in detail with reference to FIGS. 21-23.

FIGS. 21-23 depict distance estimations by a DDT autoencoder 2100 according to one particular, non-limiting exemplary embodiment of the disclosed concept. The DDT autoencoder 2100 takes input data x and outputs the distance between the input x and the decoded data \hat{x}. FIG. 21 shows a block diagram of the DDT autoencoder 2100 according to one particular, non-limiting exemplary embodiment of the disclosed concept. The input data 2101 is inputted to a bus tap 2405, which distributes copies of the input data 2101 to K DDT engines 2410₀, 2410₁, 2410_{k,1}, each tree representing one latent dimension. The output from the DDT engines 2410₀, 2410₁, 2410ₖ₋₁ are inputted to the distance determiner 2015, which then computes the distance Δ with respect to the input data 2101. The DDT engines 2410₀, 2410₁, 2410ₖ₋₁ output a vector estimates \hat{x}. The distance determiner 2015 receives the outputs of the DDT engines 2410₀, 2410₁, 2410ₖ₋₁ and computes the distance for each set of the outputs. The computed distances are added by a summer 2017. For each estimate \hat{x}ₖ a distance function (e.g., Manhattan distance) 2016₀, 2016₁, 2016ₖ₋₁ is used. The total distance 2230 for the forest is the sum of the individual distance as follows:

Δ=Σₖ₌₀^{K-1}Δₖ EQ. 30

where Δₖ=Σᵥ₌₀^{v-1}|\hat{x}_{k,v}−xᵥ| (K indexes the DDTs, V is a variable). The total distance 2230 is the measure of the anomaly. The DDT engines 2410₀, 2410₁, 2410ₖ₋₁ act as both the encoder and the decoder. The DDT engines 2410₀, 2410₁, 2410ₖ₋₁ find bin location when acting as an encoder. The bin index represented the encoded data w. The DDT engines 2410₀, 2410₁, 2410ₖ₋₁ then find bin estimates when acting as a decoder. The lookup table 520′ may be modified in that the autoencoder 2100 needs not look up the decision tree output score stored in the lookup table 520′, and the lookup table 520′ only needs to store information about the terminal leaf.

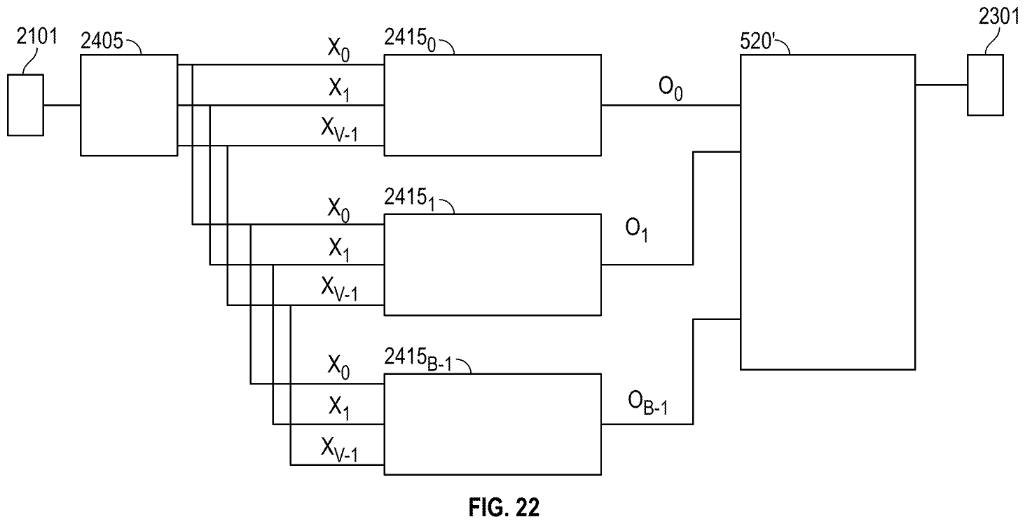

FIG. 22 is a block diagram of the DDT engine 2410 according to one particular, non-limiting exemplary embodiment of the disclosed concept. The input data x is a vector of V variables (x₀, x₁, xᵥ₋₁) and the output data \hat{x} is the corresponding set of estimates. For each bin B (terminal node) of the DDT, there is a corresponding one hot decision path (OHDP) 2415₀, 2415₁, 2415_{B-1}, which yields a boolean. The modified look-up table 520′ may be used to convert the one-hot input to the estimate \hat{x}.

FIG. 23 is a block diagram of one hot decision path (OHDP) 2415 according to one particular, non-limiting exemplary embodiment of the disclosed concept. Each variable xᵥ for input data x is compared by a comparator 2420 to a pair of low and high constants α to check if the variable is within the range defined by the constants, i.e., α_{low}<xᵥ<α_{high}. The collection of the pairs of the comparisons for each variable defines a particular decision path. The output from the comparators 2420 is inputted to the AND gate 2422, which then outputs the encoded OHDP 2415.

FIGS. 24A-E illustrate ML training of deep decision tree (DDT) on decision tree grid (DTG) according to one particular, non-limiting exemplary embodiment of the disclosed concept. FIG. 24A shows an example input data represented as an x-y scatter plot in 1D projection. FIG. 24B shows the input data 2101 being split. A threshold is generated by sampling the 1D projection with the highest normalized frequency to split the scatter plot of the input data 2101. FIGS. 24C-E illustrate training of the DDT autoencoder 2100 in an iterative manner. FIG. 24C shows DTG diagram 2222 with seven bins upon adding the partitions iteratively. This DTG 2222 is sent to be synthesized in the firmware 2060. FIGS. 24D-E show the DDTs 2200 with maximum depth of four and corresponsive decision paths 2415. In principle, a look up bin engine of device 10 may be modified to output a set of quantities, i.e., \hat{x}={\hat{x}₀, \hat{x}₁, . . . , \hat{x}ᵥ₋₁}, rather than one quality in the output score O_{BDT}. The decision path design may loop over the decision path, rather than over each variable as is looped by the unmodified look up bin engine. The decision path design flattens the plurality of logical paths to a single parallel scheme, whereas the look up bin engine only flattens the plurality of binary splits of the decision tree to a single plurality split of a unit depth tree. This modification allows considering decision trees of arbitrary depth.

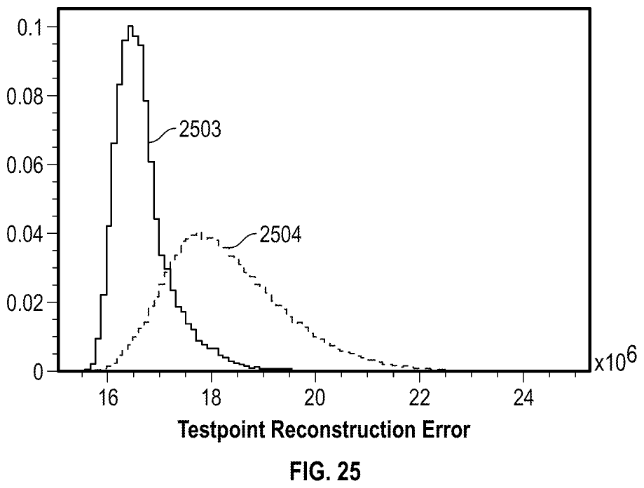

FIG. 25 illustrates anomaly score distributions according to one particular, non-limiting exemplary embodiment of the disclosed concept. FIG. 25 illustrates anomaly score distributions for a standard model background process 2503 and a different scenario involving a hypothetical scalar particle decaying to four electrons or muons 2504. The anomalies were detected by the DDT autoencoder 2100, which is trained on background processes. In other words, the DDT autoencoder 2100 was configured only using a sample containing the anomaly score distributions for the standard model background process 2503. After it was configured using fwXae 2000, it was deployed on another sample containing 2503 mixed in with a sample containing 2504. The DDT autoencoder, which had no previous knowledge of 2504 was able to detect it by giving a score that is statistically higher than 2503. The DDT using the decision path (DP) architecture gives two advantages. First, the DDT encodes decision trees of arbitrary depth (e.g., without limitation, at a depth of 10), which allows for an efficient implementation on FPGA compared to a flattened decision tree architecture. Second, the DDT using the DP architecture allows for a fast implementation on FPGA compared to the traditional iterative design. These two considerations allow for a more efficient and fast hardware implementation of the anomaly score than traditional approaches. Therefore, traditional approaches with similar efficiency in implementation and latency would be less performant, i.e., the anomaly score for input data would be closer with respect to the peak of the training sample, with respect to the result using DDT.

FIG. 26 illustrates nanosecond data-transmission of encoded data using a DDT autoencoder 2100 according to one particular, non-limiting exemplary embodiment of the disclosed concept. The input data 2101 is inputted to a bus tap 2405, which inputs copies of the input data (x) 2101 to the modified lookup bin engines 2400. In FIG. 26, the modified lookup bin engines 2400 are different from the DDT engines 2410₀, 2410₁, 2410ₖ₋₁ of FIG. 21 in that the modified bin engines 2400 are split into bin engines 2412₀, 2412₁, 2412ₖ₋₁ and lookup tables 520′₀, 520′₁, 520′_{K}. The bin engines 2412₀, 2412₁, 2412ₖ₋₁ act as encoder 2110 and the lookup tables 520′₀, 520′₁, 520′_{K-1} act as decoder 2150. The bin engines 2412₀, 2412₁, 2412ₖ₋₁ may be disposed on on-detector electronics, or edge electronics near the sensor, 2071 such as an ASIC. The lookup tables 520′₀, 520′₁, 520′_{K-1} may be disposed on off-detector electronics, or electronics far from the sensor, 2070 such as an FPGA. The data transmitter 2600 receives the encoded data w from each bin engines and transmits the encoded data to the lookup tables 520′₀, 520′₁, 520′_{K-1}. The lookup tables 520′₀, 520′₁, 520′_{K-1} finds bin estimates (reconstructed data \hat{x}) when acting as a decoder. The lookup tables 520′₀, 520′₁, 520′_{K-1} send the reconstructed data \hat{x} to the distance determiner 2015, which in turn computes the distance between the input data 2101 and the reconstructed data \hat{x}. If computed distance indicates faithful reconstruction of the input data 2101, the distance determiner 2015 transmits the reconstructed data \hat{x} to a user within less than, e.g., without limitation, tens of nanoseconds. The reconstructed data \hat{x} is the faithful reconstruction of the input data 2101 if the computed distance is within a threshold, e.g., without limitation, less than a user specified value.

FIG. 27 illustrates a DDT autoencoder 2100 configured to perform continuous self-aware ML training according to one particular, non-limiting exemplary embodiment of the disclosed concept. An autoencoder does not need supervision, but it still needs to be trained. Rather than the conventional training models of supervised training, where the parameters of the ML are adjusted according to its ability to separate, e.g., signal and background samples, the autoencoder ML training only requires just one sample. As such, past data are typically chosen to train the autoencoder. ML training determines the parameters of the autoencoder. For decision trees, the training determines the set of cut thresholds. There are four ML training options for an autoencoder: random, uniform, importance, and distance. Random ML training method trains the autoencoder by training random forests, where external ML software such as scikit-learn may be used to generate forests with random splits. This method can provide a robust autoencoder, but it is not optimized for anomaly detection since it has been shown that reconstruction distance from anomalous events does not significantly deviate from training event distance. The distance ML training method uses stochastic gradient descent. By training to minimize reconstruction distance on the training set, this method may be used for anomaly detection application. However, it has been shown that rather than providing the “hard” cuts that can be used to create a DTG, this methods creates “soft” multivariate cuts using gating functions at the nodes. As such, the distance ML training method cannot be easily optimized for firmware. The uniform ML training method trains the autoencoder by distributing cuts uniformly in the range of each input variable. For the implementation, importance trainer is used to optimize the cut thresholds for the reconstruction of non-anomaly background events. For each variable, gaussian kernel density estimation (KDE) is used to obtain a univariate probability density function (PDF). The PDF is randomly sampled C times, yielding C cuts with a density following that of the variable distribution. It is designed to minimize the reconstruction distance Δ of the training sample for the variable under consideration. However, an anomalous event falling outside these areas of high variable density for one or more variables will land in a region with less fine binning. For example, an event with low x and high y may, in general, have a higher Δ than most background events may have. In this way, the Δ can be used as a metric for detecting anomalies, with higher values indicating a larger deviation from the background. As with decision trees, improved performance is obtained by creating a set of DTG and combining the subsequent results.

Referring back to FIG. 27, the input data 2101-2104 is inputted to a bus tap 2405, which copies the input data x and transmit them to the DDT autoencoder 2100 including modified look up bin engines 2400 and to ML trainer 2020. The DDT autoencoder 2100 receives the copied input data and the modified lookup bin engines encode the input data and decodes the encoded data simultaneously. The DDT autoencoder 2100 outputs the decoded data to the distance determiner 2015 and/or estimator 2014. An estimate \hat{x} is output to the user. If the reconstructed data or estimate \hat{x} is a faithful reconstruction of the input data x, then the autoencoder 2100 is utilized as a nanosecond encoded data transmitter. If the reconstructed data \hat{x} is an errant reconstruction indicating a very large distance between the input data x and the reconstructed data \hat{x}, the DDT autoencoder 2100 is utilized as nanosecond anomaly detector. The user may also input 2035 information, e.g., without limitation updated frequency, to the ML trainer 2020 as desired for the continuous self aware ML training. The DDT autoencoder 2100 may be included in a programmable logic 2072 coupled to the ML trainer 2020 including a histogram manager 2021 and a coefficient reloader 2024. The histogram manager 2021 includes histogram engine 2022 and training engine 2023. The histogram engine 2022 is configured to transmit historical data (e.g., all input data x) to memory 2025 for storing the historical data. The memory 2025 can be any of one or more of a variety of types of internal and/or external storage media such as, without limitation, RAM, ROM, EPROM(s), EEPROM(s), FLASH, and the like that provide a storage register, i.e., a machine readable medium, for data storage such as in the fashion of an internal storage area of a computer, and can be volatile memory. The memory 25 is accessible by a USB via a USB controller 2080 for storing the historical data from the memory 25 to non-volatile memory in, e.g., hard drive 2026 for further offline study of the historical data.

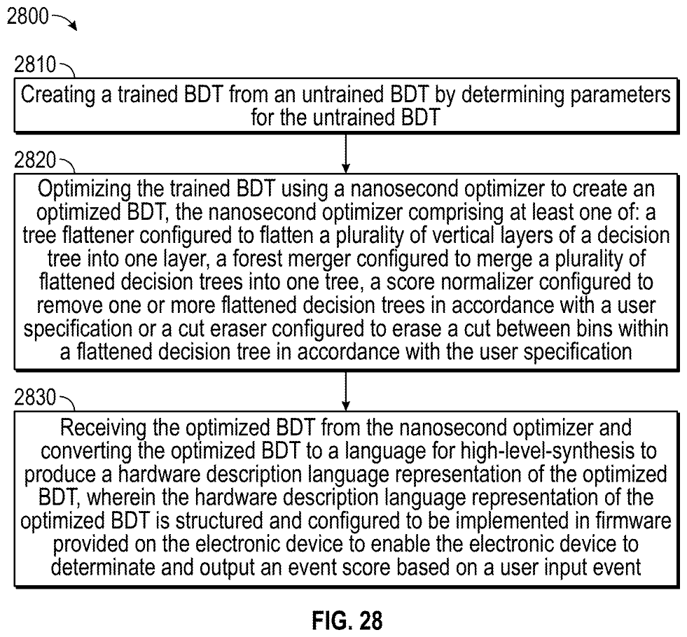

FIG. 28 is a flow chart for a method 2800 for providing a boosted decision tree (BDT) for use on an electronic device to provide an event score based on a user input event according to one particular, non-limiting exemplary embodiment of the disclosed concept. The method 2800 may be performed by the device 10 (as shown in FIG. 1) configured to optimize machine learning algorithm execution and any of its component thereof.

At 2810, the device creates a trained BDT from an untrained BDT by determining parameters for the untrained BDT.

At 2820, the device optimizes the trained BDT using a nanosecond optimizer to create an optimized BDT, the nanosecond optimizer comprising at least one of: a tree flattener configured to flatten a plurality of vertical layers of a decision tree into one layer, a forest merger configured to merge a plurality of flattened decision trees into one tree, a score normalizer configured to remove one or more flattened decision trees in accordance with a user specification or a cut eraser configured to erase a cut between bins within a flattened decision tree in accordance with the user specification.

At 2830, the device receives the optimized BDT from the nanosecond optimizer and converting the optimized BDT to a language for high-level-synthesis to produce a hardware description language representation of the optimized BDT, wherein the hardware description language representation of the optimized BDT is structured and configured to be implemented in firmware provided on the electronic device to enable the electronic device to determinate and output an event score based on a user input event.

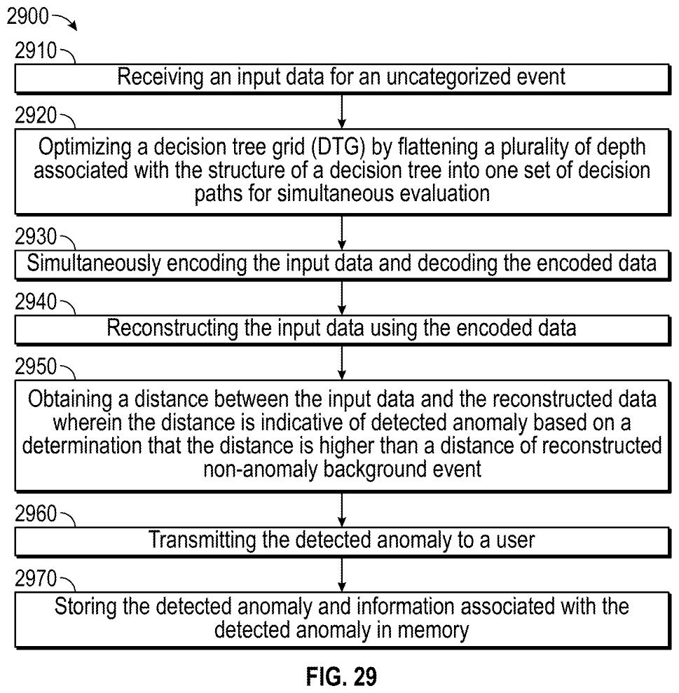

FIG. 29 is a flow chart for a method 2900 of nanosecond anomaly detection using an autoencoder with a decision tree grid (DTG) according to one particular, non-limiting exemplary embodiment of the disclosed concept. The method 2900 may be performed by the autoencoder system 2000 and any of its component thereof.

At 2910, the autoencoder receives an input data for an uncategorized event.

At 2920, the nanosecond optimizer of the autoencoder optimizes a decision tree grid (DTG) by flattening a plurality of depth associated with the structure of a decision tree into one set of decision paths for simultaneous evaluation.

At 2930, the autoencoder simultaneously encodes the input data and decodes the encoded data.

At 2940, the estimator reconstructs the input data using the encoded data.

At 2950, the distance determiner obtains a distance between the input data and the reconstructed data, wherein the distance is indicative of detected anomaly based on a determination that the distance is higher than a distance of reconstructed non-anomaly background event.

At 2960, a transmitter or the estimator transmits the detected anomaly to a user.

At 2970, machine learning trainer stores the detected anomaly and information associated with the detected anomaly in memory.

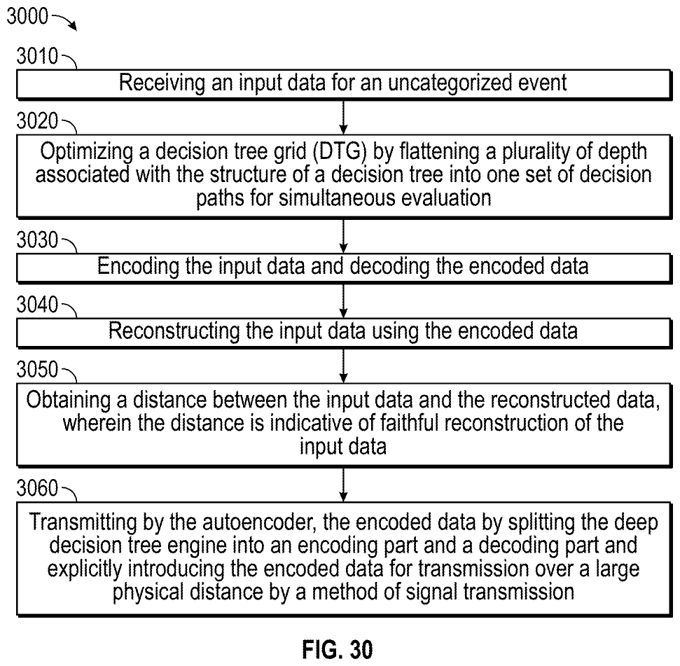

FIG. 30 is a flow chart for a method 3000 of nanosecond data transmission using an autoencoder with a decision tree grid (DTG) according to one particular, non-limiting exemplary embodiment of the disclosed concept. The method 3000 may be performed by the autoencoder system 2000 and any of its component thereof.

At 3010, the autoencoder receives an input data for an uncategorized event.

At 3020, the nanosecond optimizer of the autoencoder optimizes a decision tree grid (DTG) by flattening a plurality of depth associated with the structure of a decision tree into one set of decision paths for simultaneous evaluation.

At 3030, the autoencoder encodes the input data and decodes the encoded data.

At 3040, the estimator reconstructs the input data using the encoded data.

At 3050, the distance determiner obtains a distance between the input data and the reconstructed data, wherein the distance is indicative of faithful reconstruction of the input data.

At 3060, the autoencoder transmits the encoded data by splitting the deep decision tree engine into an encoding part and a decoding part and explicitly introducing the encoded data for transmission over a large physical distance by a method of signal transmission.

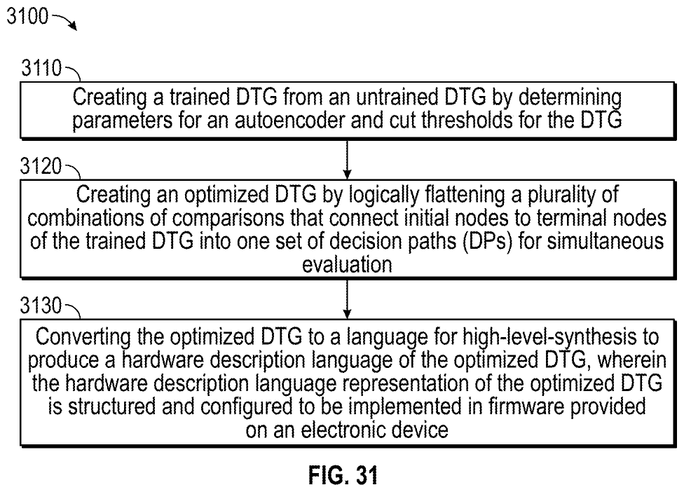

FIG. 31 is a flow chart for a method 3100 of nanosecond data transmission using an autoencoder with a decision tree grid (DTG) according to one particular, non-limiting exemplary embodiment of the disclosed concept. The method 3100 may be performed by the autoencoder system 2000 and any of its component thereof.

At 3110, the autoencoder creates a trained DTG from an untrained DTG by determining parameters for an autoencoder and cut thresholds for the DTG.

At 3120, the autoencoder creates an optimized DTG by logically flattening a plurality of combinations of comparisons that connect initial nodes to terminal nodes of the trained. DTG into one set of decision paths (DPs) for simultaneous evaluation.

At 3130, the autoencoder converts the optimized DTG to a language for high-level-synthesis to produce a hardware description language of the optimized DTG, wherein the hardware description language representation of the optimized DTG is structured and configured to be implemented in firmware provided on an electronic device. The firmware is configured to receive the hardware description language representation and includes: (i) a plurality of deep decision tree engines configured to receive copies of the input data and evaluating each decision path independently from a plurality of depths associated with a structure of a decision tree, and (ii) a processing portion configured to process outputs from the plurality of deep decision tree engines, the processing portion comprising an estimator configured to reconstruct the input data using the encoded data and a distance determiner configured to determine a distance between the input and the reconstructed data.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot he used in combination.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

What is claimed is:

1. A system for providing a boosted decision tree (BDT) for use on an electronic device to provide an event score based on a user input event, comprising:
a device configured to optimize nanosecond execution of a machine learning algorithm, wherein the device comprises:
a. a machine learning trainer configured to create a trained BDT from an untrained BDT by determining parameters for the untrained BDT;
b. a nanosecond optimizer configured to optimize the trained BDT to create an optimized BDT, the nanosecond optimizer comprising at least one of:
i. a tree flattener configured to flatten a plurality of vertical layers of a decision three into one layer,
ii. a tree merger configured to merge a plurality of flattened decision trees into one tree,
iii. a score normalizer configured to normalize an event score of a bin of a flattened tree,
iv. a tree remover configured to remove one or more flattened decision trees in accordance with a user specification, or
v. a cut eraser configured to erase a cut between bins within a flattened decision tree in accordance with the user specification; and
c. a converter coupled to the nanosecond optimizer and configured to receive the optimized BDT from the nanosecond optimizer and convert the optimized BDT to a language for high-level-synthesis to produce a hardware description language representation of the optimized BDT, wherein the hardware description language representation of the optimized BDT is structured and configured to be implemented in firmware provided on the electronic device to enable the electronic device to determinate and output an event score based on a user input event.

2. The system of claim 1, wherein the electronic device is a Field Programmable Gate Array and the nanosecond execution of machine learning algorithm in the FPGA is performed in as low as two clock ticks.

3. The system of claim 1, wherein the nanosecond optimizer eliminates firmware-side multiplications in calculating a weighted average of the event score, thereby reducing latency and increasing efficiency of the system.

4. The system of claim 1, wherein the nanosecond optimizer further comprises a score finder configured to find the event score of the bin of the flattened tree.

5. The system of claim 1, wherein the firmware performs a bit-shift-ready linear piecewise approximation of a nonlinear function within a predefined range.

6. The system of claim 1, wherein the nanosecond optimizer further comprises a staircase approximation of diagonal cuts across an n-dimensional gridspace.

7. The system of claim 1, wherein bit-shifting acts as a division operator for divisions requiring a same divisor such that bit-shifting reduces latency and increases the efficiency of the system.

8. The system according to claim 1, wherein the nanosecond optimizer comprises at least the tree flattener and the forest merger.

9. The system of claim 1, wherein the device further includes:
a lookup table coupled to the nanosecond optimizer, the lookup table comprising a plurality of data including predefined bin-indexed event scores based on event testing at each node of the flattened decision trees, and
a firmware coupled to the converter and the lookup table, the firmware configured to receive the hardware description language representation, wherein the firmware comprises a bin engine configured to determine a bin index associated with a node of the flattened decision trees via bit shilling or using bin addresses for accessing the lookup table.

10. A method for providing a boosted decision tree (BDT) for use on an electronic device to provide an event score based on a user input event, the method comprising:
creating a trained BDT from an untrained BDT by determining parameters for the untrained BDT;
optimizing the trained BDT using a nanosecond optimizer to create an optimized BDT, the nanosecond optimizer comprising at least one of:
i. a tree flattener configured to flatten a plurality of vertical layers of a decision three into one layer,
ii. a forest merger configured to merge a plurality of flattened decision trees into one tree.
iii. a score normalizer configured to normalize an event score of a bin of a flattened tree,
iv. a tree remover configured to remove one or more flattened decision trees in accordance with a user specification, or
v. a cut eraser configured to erase a cut between bins within a flattened decision tree in accordance with the user specification; and
receiving the optimized BDT from the nanosecond optimizer and converting the optimized BDT to a language for high-level-synthesis to produce a hardware description language representation of the optimized BDT, wherein the hardware description language representation of the optimized Bar is structured and configured to be implemented in firmware provided on the electronic device to enable the electronic device to determinate and output an event score based on a user input event.

11. The method of claim 10, wherein the electronic device is a Field Programmable Gate Array, and the nanosecond execution of machine learning algorithm is performed in as low as two clock ticks.

12. The method of claim 10, wherein the device further includes:
a lookup table coupled to the nanosecond optimizer, the lookup table comprising a plurality of data including predefined bin-indexed event scores based on event testing at each node of the flattened decision trees, and
a firmware coupled to the converter and the lookup table, the firmware configured to receive the hardware description language representation, wherein the firmware comprises a bin engine configured to determine a bin index associated with a node of the flattened decision trees via bit shifting or using bin addresses for accessing the lookup table.

13. The method of claim 10, wherein the nanosecond optimizer comprises at least the tree flattener and the forest merger.

14. An electronic device, comprising: firmware implementing an optimized boosted decision tree (BDT) generated from an untrained BDT by:
creating a trained BDT from the untrained BDT by determining parameters for the untrained BDT;
optimizing the trained BDT using a nanosecond optimizer to create an optimized BDT, the nanosecond optimizer comprising at least one of:
i. a tree flattener configured to flatten a plurality of vertical layers of a decision three into one layer,
ii. a forest merger configured to merge a plurality of flattened decision trees into one tree,
iii. a score normalizer configured to normalize an event score of a bin of a flattened tree,
iv. a tree remover configured to remove one or more flattened decision trees in accordance with a user specification, or
v. a cut eraser configured to erase a cut between bins within a flattened decision tree in accordance with the user specification; and
converting the optimized BDT to a language for high-level-synthesis to produce a hardware description language representation of the optimized BDT, wherein the firmware implements the hardware description language representation of the optimized BDT.

15. A method of determining event scores using a device configured to be implemented in an electronic device for optimizing nanosecond execution of machine learning algorithm, comprising:
receiving an input data for an uncategorized event;
determining a bin index associated with the input data by bit-shifting or using bin addresses for accessing a lookup table comprising a plurality of data including predefined bin indices based on event testing;
determining an event score associated with the input data; and
outputting the event score to a user device.

16. An autoencoder system, comprising:
a. an autoencoder configured to receive input data, encode the input data and decode the encoded data using a decision tree grid (DTG), wherein the autoencoder comprises:
i. a machine learning (ML) trainer configured to determine parameters for the autoencoder and cut thresholds for the DTG using an importance trainer to create a trained DTG from an untrained DTG;
ii. a nanosecond optimizer comprising a decision path (DP) architecture for creating an optimized DTG by logically flattening a plurality of combinations of comparisons that connect initial node to terminal nodes of the trained DTG into one set of DPs for simultaneous evaluation:
iii. a converter coupled to the autoencoder and configured to receive the optimized DTG and convert the optimized DTG to a language for high-level-synthesis to produce a hardware description language representation of the optimized DTG, wherein the hardware description language representation of the optimized DTG is structured and configured to be implemented in firmware provided on an electronic device, and
wherein the firmware is configured to receive the hardware description language and comprises:
i. a plurality of deep decision tree (DDT) engines configured to receive copies of the input data and evaluate each decision path independently from a plurality of depth associated with a structure of a decision tree; and
ii. a processing portion configured to process outputs from the plurality of deep decision tree engines, the processing portion comprising an estimator configured to reconstruct the input data using the encoded data and a distance determiner configured to determine a distance between the input and the reconstructed data.

17. The system of claim 16, wherein the distance is indicative of detected anomaly based on a determination that the distance is farther than a distance of reconstructed non-anomaly background event and the detected anomaly is transmitted to a user and stored in memory for ML training.

18. The system of claim 16, wherein the distance is indicative of faithful reconstruction of the input data and the autoencoder is further configured to transmit the encoded data by splitting the deep decision tree engines into an encoding part and a decoding part and explicitly introducing the encoded data that are transmitted over a large physical distance by a method of signal transmission.

19. The system of claim 16, wherein electronic device is a Field Programmable Gate Array.

20. The system of claim 16, wherein the DTG acts as encoder and decoder and performs encoding and decoding simultaneously, and the autoencoder bypasses production of latent space data.

21. The system of claim 16, wherein the DTG utilizes a deep decision tree engine based on the simultaneous evaluation of the one set of decision paths, each decision path localizing the input data according to upper and lower bounds on each input variable.

22. The system of claim 16, wherein the DTG stores information about a terminal leaf of the decision tree in the form of bin indices as the encoded data and does not store a unique score of the terminal leaf.

23. The system of claim 18, wherein the autoencoder is self trained periodically according to user specifications by the importance trainer using one-sample training data in an unsupervised manner by using the input data simultaneously stored in memory.

24. A method for nanosecond execution of an autoencoder with a decision tree grid (DTG), comprising:
creating a trained DTG from an untrained DTG by determining parameters for the autoencoder and cut thresholds for the DTG;
creating an optimized DTG by logically flattening a plurality of combinations of comparisons that connect initial nodes to terminal nodes of the trained DTG into one set of decision paths (DPs) for simultaneous evaluation;
converting the optimized DTG to a language for high-level-synthesis to produce a hardware description language representation of the optimized. DTG, wherein the hardware description language representation of the optimized DTG is structured and configured to be implemented in firmware provided on an electronic device,
wherein the firmware is configured to receive the hardware description language representation and comprises:
(i) a plurality of deep decision tree engines configured to receive copies of the input data and evaluating each decision path independently from a plurality of depths associated with a structure of a decision tree, and
(ii) a processing portion configured to process outputs from the plurality of deep decision tree engines, the processing portion comprising an estimator configured to reconstruct the input data using the encoded data and a distance determiner configured to determine a distance between the input and the reconstructed data.

25. The method of claim 24, wherein the distance is indicative of detected anomaly based on a determination that the distance is farther than a distance of reconstructed non-anomaly background event and the detected anomaly is transmitted to a user and stored in memory for ML training.

26. The method of claim 24, wherein the distance is indicative of faithful reconstruction of the input data and the autoencoder is further configured to transmit the encoded data by splitting the deep decision tree engines into an encoding part and a decoding part and explicitly introducing the encoded data that are transmitted over a large physical distance by a method of signal transmission.

27. The method of claim 24, wherein the electronic device is a Field Programmable Gate Array.

28. The method of claim 24, wherein the DTG acts as encoder and decoder and performs encoding and decoding simultaneously, and the autoencoder bypasses production of latent space data.

29. The method of claim 24, wherein the DTG utilizes a deep decision tree engine based on the simultaneous evaluation of the one set of decision paths, each decision path localizing the input data according to upper and lower bounds on each input variable.

30. The method of claim 22, wherein the DTG stores information about a terminal leaf of the decision tree in the form of bin indices as the encoded data and does not store a unique score of the terminal leaf.

31. The method of claim 22, wherein the autoencoder is self trained periodically according to user specifications by the importance trainer using one-sample training data in an unsupervised manner by using the input data simultaneously stored in memory.

37. An electronic device, comprising: firmware implementing an optimized decision tree grid (DTG) generated from an untrained DTG by:
creating a trained DTG from an untrained DTG by determining parameters for an autoencoder and cut thresholds for the DTG;
creating an optimized DTG by logically flattening a plurality of combinations of comparisons that connect initial nodes to terminal nodes of the trained DTG into one set of DPs for simultaneous evaluation;
converting the optimized DTG to a language for high-level-synthesis to produce a hardware description language of the optimized DTG, wherein the hardware description language representation of the optimized DTG is structured and configured to be implemented in firmware provided on an electronic device and wherein the firmware comprises:
i. a plurality of deep decision tree (DDT) engines configured to receive copies of the input data and evaluate each decision path independently from a plurality of depths associated with a structure of a decision tree; and
ii. a processing portion configured to process outputs from the plurality of deep decision tree engines, the processing portion comprising an estimator configured to reconstruct the input data using the encoded data and a distance determiner configured to determine a distance between the input and the reconstructed data.

33. A method of nanosecond execution of an autoencoder with a decision tree grid (DTG), comprising:
receiving an input data for an uncategorized event;
optimizing the DTG by flattening a plurality of depth associated with the structure of a decision tree into one set of combinations comprising one DP for simultaneous evaluation;
encoding the input data and decoding the encoded data;
reconstructing the input data using the encoded data; and
computing a distance between the input data and the reconstructed data.

34. The method of claim 33, wherein the encoding the input data and decoding the encoded data occur simultaneously, the method further comprising:
transmitting detected anomaly to a user, wherein the distance is indicative of the detected anomaly based on a determination that the distance is higher than a distance of reconstructed non-anomaly background event; and
storing the detected anomaly and information associated with the detected anomaly in memory.

35. The method of claim 33, further comprising:
transmitting the encoded data by splitting the deep decision tree engine into an encoding part and a decoding part and explicitly introducing the encoded data for transmission over a large physical distance by a method of signal transmission, wherein the distance is indicative of faithful reconstruction of the input data; and
storing at least the input data and the encoded data in memory.

36. The method of claim 33, wherein the autoencoder is implemented in a Field Programmable Gate Array.
